(19) United States
(12) Patent Application Publication
(10) Pub. No.: US 2019/0139617 A1
(43) Pub. Date: May 9, 2019

(54) TRANSISTOR AND SHIFT REGISTER

(71) Applicant: SHARP KABUSHIKI KAISHA, Sakai City (JP)

(72) Inventors: YASUSHI SASAKI, Sakai City (JP); YUHICHIROH MURAKAMI, Sakai City (JP); SHIGE FURUTA, Sakai City (JP); TAKAHIRO YAMAGUCHI, Sakai City (JP)

(21) Appl. No.: 16/177,440

(22) Filed: Nov. 1, 2018

(30) Foreign Application Priority Data
Nov. 6, 2017 (JP) 2017-213673

(51) Int. Cl. G11C 19/28; H01L 29/786; G02F 1/1345; G02F 1/1362; G02F 1/1368; G09G 3/36

(52) U.S. Cl. CPC G11C 19/287; H01L 29/78633; G02F 1/13454; G02F 1/136286; G09G 2310/08; G09G 3/3677; G09G 3/3688; G09G 2310/0286; G09G 2300/0426; G02F 1/1368

(57) ABSTRACT

A transistor includes gate electrodes and light blocking films. The light blocking films are provided in a layer lower than a layer in which the gate electrodes are provided, overlap the respective gate electrodes as viewed in a plan view, shield a channel portion from light, and are electrically isolated.

### BACKGROUND

### 1. Field

The present disclosure relates to transistors and shift registers.

### 2. Description of the Related Art

Thin-film transistors, upon being irradiated with light, undergo a shift in their characteristics. Therefore, it is known to date that a light blocking film is disposed underneath a channel portion of a thin-film transistor in order to shield the thin-film transistor from light irradiation in a display device. An example of a driving circuit in which such a technique is employed is disclosed in International Publication No. WO2016/190187.

Disclosed in International Publication No. WO2016/190187 is a driving circuit for a display device that is formed on a display panel, and the driving circuit includes a thin-film transistor having a first conducting electrode, a second conducting electrode, and a control electrode; an electrically isolated light blocking film having a main body portion that shields a channel portion of the thin-film transistor from light and an extension portion formed integrally with the main body portion; and an auxiliary capacitor formed as the extension portion of the light blocking film and an electrode member overlap each other as viewed in a plan view.

In the driving circuit of the related art, since the auxiliary capacitor needs to be added to the transistor, the size of the transistor increases, and the size of the driving circuit may increase in turn.

To address the above, the present disclosure is directed to shielding a channel portion from light without increasing the size of a transistor.

### SUMMARY

A transistor according to an aspect of the present disclosure includes a channel portion, a first conducting electrode, a second conducting electrode, a plurality of control electrodes, and a plurality of light blocking films provided in a layer lower than a layer in which the plurality of control electrodes are provided. The plurality of light blocking films overlap the respective control electrodes as viewed in a plan view. The plurality of light blocking films shield the channel portion from light. The plurality of light blocking films are electrically isolated.

### BRIEF DESCRIPTION OF THE DRAWINGS

FIG. 1 is a block diagram illustrating a configuration of a liquid crystal display device according to a first embodiment;

FIG. 2 is a block diagram illustrating a configuration of a shift register provided in a scanning line driving circuit according to the first embodiment;

FIG. 3 is a circuit diagram of a unit circuit according to the first embodiment;

FIG. 4 is a timing chart illustrating a normal operation of the shift register according to the first embodiment;

FIG. 5 illustrates a configuration of a transistor according to the first embodiment;

FIG. 6 is a schematic diagram illustrating an equivalent circuit of the transistor according to the first embodiment;

FIG. 7 is a timing chart illustrating a normal operation of the shift register in a case in which a transistor included in the unit circuit according to the first embodiment includes a light blocking film;

FIG. 8 illustrates a transistor according to a comparative example;

FIG. 9 illustrates an equivalent circuit of the transistor according to the comparative example;

FIG. 10 is a timing chart illustrating a normal operation of a shift register in a case in which a transistor included in a unit circuit according to the comparative example includes no light blocking film;

FIG. 11 is a configuration diagram of a unit circuit according to a second embodiment;

FIG. 12 is a block diagram illustrating a configuration of a liquid crystal display device that includes a scanning line driving circuit according to a third embodiment;

FIG. 13 illustrates details of one vertical interval held when the liquid crystal display device according to the third embodiment operates;

FIG. 14 is a circuit diagram of a unit circuit according to the third embodiment;

FIG. 15 is a timing chart illustrating a normal operation of a shift register according to the third embodiment;

FIG. 16 is a block diagram illustrating a configuration of a shift register included in a scanning line driving circuit according to a fourth embodiment;

FIG. 17 illustrates a configuration example of a switching circuit according to the fourth embodiment;

FIG. 18 illustrates another configuration example of the switching circuit according to the fourth embodiment;

FIG. 19 is a timing chart illustrating a normal operation of the shift register according to the fourth embodiment;

FIG. 20 is a block diagram illustrating a configuration of a shift register included in a scanning line driving circuit according to a fifth embodiment;

FIG. 21 illustrates a configuration of a unit circuit according to the fifth embodiment;

FIG. 22 is a timing chart illustrating a normal operation of the shift register according to the fifth embodiment;

FIG. 23 illustrates a configuration example of a unit circuit according to a sixth embodiment;

FIG. 24 illustrates a configuration example of a unit circuit according to a seventh embodiment;

FIG. 25 illustrates a configuration example of a transistor according to an eighth embodiment;

FIG. 26 illustrates another configuration example of the transistor according to the eighth embodiment; and

FIG. 27 illustrates a configuration example of a unit circuit provided in a shift register according to a ninth embodiment.

### DESCRIPTION OF THE EMBODIMENTS

### First Embodiment

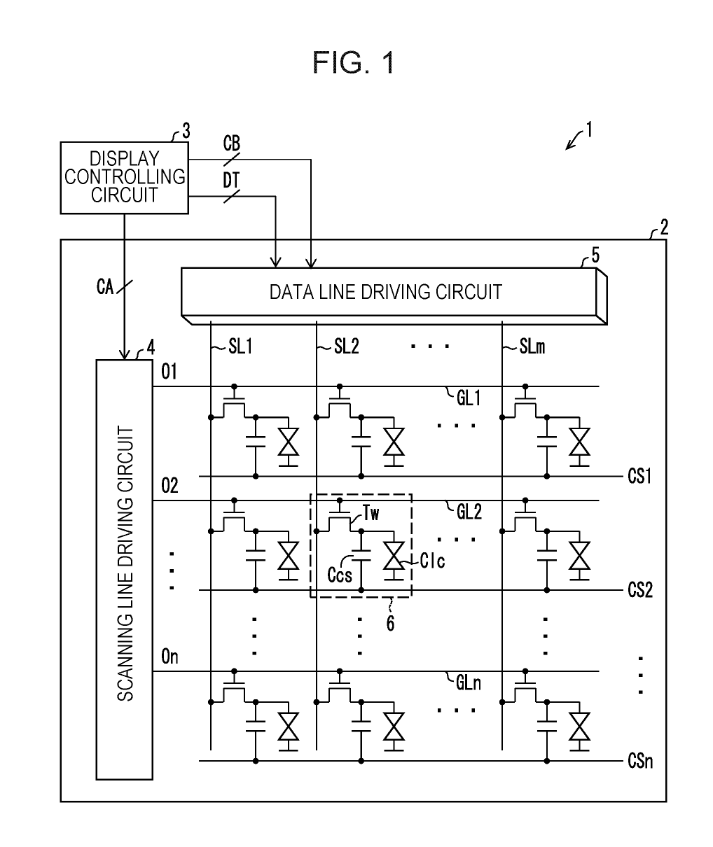

FIG. 1 is a block diagram illustrating a configuration of a liquid crystal display device 1 (display device) according to a first embodiment. The liquid crystal display device 1 illustrated in FIG. 1 includes a liquid crystal panel 2 (display unit), a display controlling circuit 3, a scanning line driving circuit 4, and a data line driving circuit 5.

The liquid crystal panel 2 includes n scanning lines GL1 to GLn, m data lines SL1 to SLm, n storage capacitance lines CS1 to CSn, and (m×n) pixel circuits 6. The scanning lines GL1 to GLn are disposed parallel to each other. The data lines SL1 to SLm are disposed orthogonal to the scanning lines GL1 to GLn and parallel to each other. The scanning lines GL1 to GLn and the data lines SL1 to SLm intersect each other at (m×n) locations. The (m×n) pixel circuits 6 are disposed in the vicinity of the respective intersections of the scanning lines GL1 to GLn and the data lines SL1 to SLm. The storage capacitance lines CS1 to CSn are disposed parallel to the scanning lines GL1 to GLn.

The pixel circuits 6 each include a transistor Tw (write-control transistor), a liquid crystal capacitor Clc, and a storage capacitor Ccs. A gate electrode of the transistor Tw is coupled to the corresponding scanning line. A source electrode of the transistor Tw is coupled to the corresponding data line. A drain electrode of the transistor Tw is coupled to one electrode of the liquid crystal capacitor Clc and one electrode of the storage capacitor Ccs. Another electrode of the liquid crystal capacitor Clc is coupled to a common electrode (not illustrated). Another electrode of the storage capacitor Ccs is coupled to the corresponding storage capacitance line. The storage capacitance lines CS1 to CSn are driven by a storage capacitance line driving circuit (not illustrated) provided outside the liquid crystal panel 2.

The scanning line driving circuit 4 and the data line driving circuit 5 are driving circuits of the liquid crystal display device 1. The scanning line driving circuit 4 drives the scanning lines GL1 to GLn, and the data line driving circuit 5 drives the data lines SL1 to SLm. The display controlling circuit 3 outputs a control signal CA to the scanning line driving circuit 4 and outputs a control signal CB and a data signal DT to the data line driving circuit 5. The scanning line driving circuit 4 successively selects one scanning line from the scanning lines GL1 to GLn in accordance with the control signal CA and applies a high-level potential to the selected scanning line. Thus, a set of m pixel circuits 6 corresponding to the selected scanning line is selected. The data line driving circuit 5 applies m voltages corresponding to the data signal DT to the respective data lines SL1 to SLm in accordance with the control signal CB. Thus, m voltages are written into the respective selected m pixel circuits 6.

The scanning line driving circuit 4 is formed on the liquid crystal panel 2 along with the pixel circuits 6 with the use of a manufacturing process that is the same as the process of manufacturing the pixel circuits 6. The data line driving circuit 5 is embedded into one or more IC chips. The IC chip(s) in which the data line driving circuit 5 is embedded is/are mounted on a surface of the liquid crystal panel 2. Herein, all or a portion of the data line driving circuit 5 may be formed on the liquid crystal panel 2 along with the pixel circuits 6 with the use of a manufacturing process that is the same as the process of manufacturing the pixel circuits 6.

The scanning line driving circuit 4 can also be disposed at the right side within the liquid crystal panel 2. Alternatively, a different scanning line driving circuit 4 can be disposed at each of the right side and the left side within the liquid crystal panel 2.

In the present embodiment, a signal that is input or output via a given terminal may be referred to by the same name as the name of that terminal in some cases (for example, a signal that is output via an output terminal OUT is referred to as an output signal OUT). In addition, a potential that, upon being provided to a gate electrode, causes a transistor to be turned on is referred to as an on-level potential, and a potential that causes a transistor to be turned off is referred to as an off-level potential. For example, in an n-channel (first conductivity type) transistor, a high-level potential is an on-level potential, and a low-level potential is an off-level potential. A threshold voltage of a transistor is designated by Vth, a high-level potential is designated by VDD, and a low-level potential is designated by VSS. In addition, m and n are each an integer no smaller than 2.

### Configuration of Shift Register 10

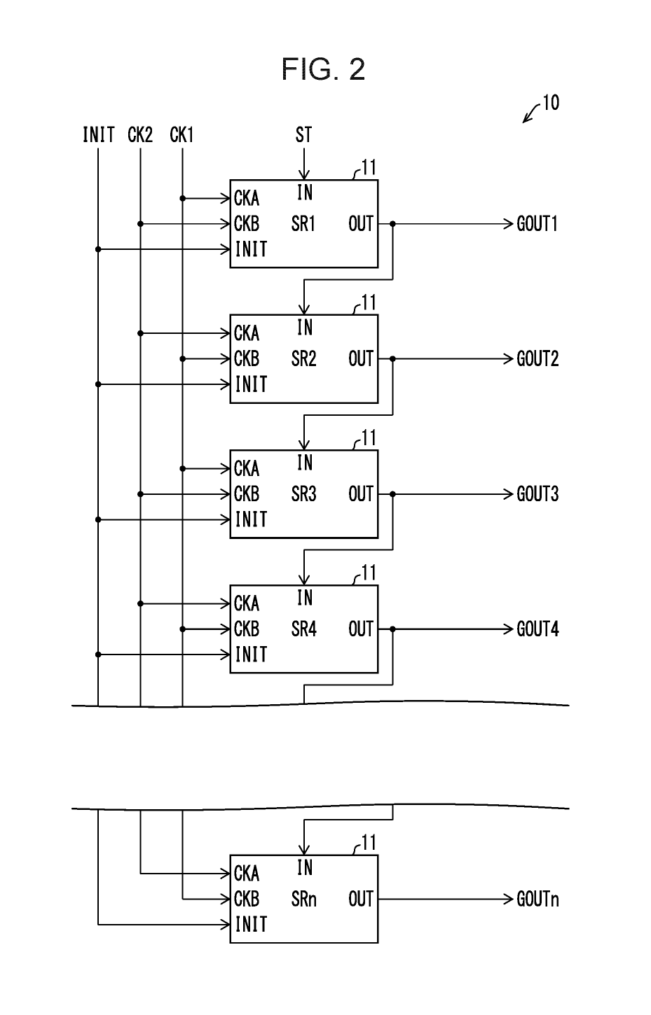

FIG. 2 is a block diagram illustrating a configuration of a shift register 10 included in the scanning line driving circuit 4 according to the first embodiment. The shift register 10 illustrated in FIG. 2 may have a configuration in which n unit circuits 11 (stages) are coupled in cascade. The unit circuits 11 may be circuits for driving respective scanning lines GL. The unit circuits 11 may each include an input terminal IN, clock terminals CKA and CKB, an initialization terminal INIT, and an output terminal OUT (output node). The output terminal OUT may be coupled to one of the scanning lines GL1 to GLn. The display controlling circuit 3 may supply, as the control signal CA, a start signal ST, two-phase clock signals CK1 and CK2, and an initialization signal INIT to the shift register 10.

As illustrated in FIG. 2, the start signal ST may be supplied to the input terminal IN of the unit circuit 11 of the first stage. The clock signal CK1 may be supplied to the clock terminals CKA of the unit circuits 11 of the odd-number stages and to the clock terminals CKB of the unit circuits 11 of the even-number stages. The clock signal CK2 may be supplied to the clock terminals CKB of the unit circuits 11 of the odd-number stages and to the clock terminals CKA of the unit circuits 11 of the even-number stages. The initialization signal INIT may be supplied to the initialization terminals INIT of the n unit circuits 11. Output signals OUT of the respective unit circuits 11 may be output outside as output signals GOUT1 to GOUTn and may each be supplied to the input terminal IN of the unit circuit 11 of the following stage. The unit circuits 11 may each be supplied with a high-level potential VDD and a low-level potential VSS from a power supply circuit (not illustrated).

### Circuit Diagram of Unit Circuit 11

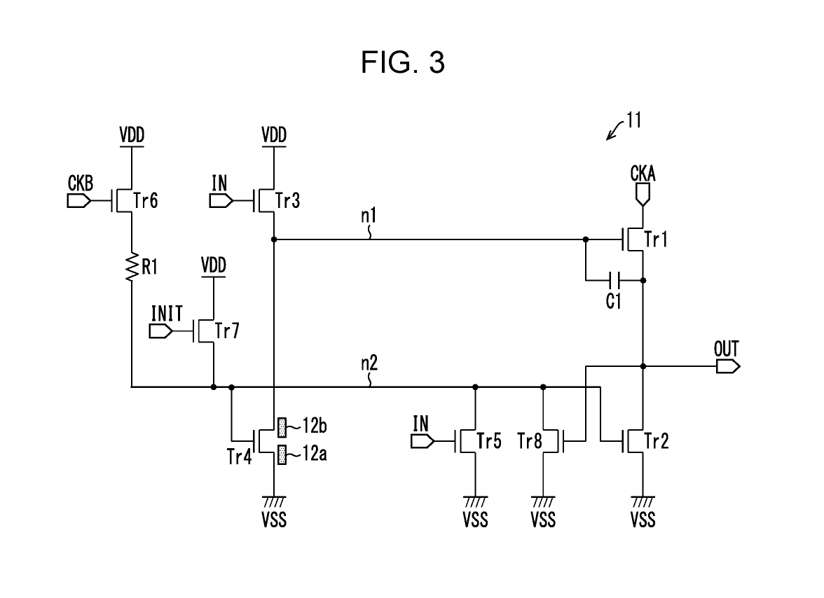

FIG. 3 is a circuit diagram of the unit circuit 11 according to the first embodiment. The unit circuit 11 illustrated in FIG. 3 may include eight transistors Tr1 to Tr8, a capacitor C1, and a resistor R1. The transistors Tr1 to Tr8 may each be an n-channel thin-film transistor (TFT).

A drain electrode of the transistor Tr1 may be coupled to the clock terminal CKA. A source electrode of the transistor Tr1 may be coupled to a drain electrode of the transistor Tr2, a gate electrode of the transistor Tr8, and the output terminal OUT. A gate electrode of the transistor Tr1 may be coupled to a source electrode of the transistor Tr3 and a drain electrode of the transistor Tr4.

A gate electrode of the transistor Tr2 may be coupled to a gate electrode of the transistor Tr4, drain electrodes of the transistors Tr5 and Tr8, a source electrode of the transistor Tr7, and one end (a lower end in FIG. 3) of the resistor R1. Gate electrodes of the transistors Tr3 and Tr5 may be coupled to the input terminal IN. A gate electrode of the transistor Tr7 may be coupled to the initialization terminal INIT. A gate electrode of the transistor Tr6 may be coupled to the clock terminal CKB, and a source electrode of the transistor Tr6 may be coupled to another end of the resistor R1.

The high-level potential VDD may be applied fixedly to drain electrodes of the transistors Tr3, Tr6, and Tr7. The low-level potential VSS may be applied fixedly to source electrodes of the transistors Tr2, Tr4, Tr5, and Tr8. The capacitor C1 may be provided between the gate electrode and the source electrode of the transistor Tr1. Hereinafter, a node to which the gate electrode of the transistor Tr1 is coupled is designated by n1 (first node), and a node to which the gate electrode of the transistor Tr2 is coupled is designated by n2 (second node).

The transistor Tr4 includes light blocking films 12a and 12b that are separated from each other. The light blocking films 12a and 12b shield a channel portion of the transistor Tr4 from light. The light blocking films 12a and 12b are not coupled to other conductive members (e.g., wires and electrodes) and are formed to be electrically isolated. The light blocking films 12a and 12b stay in a floating state. It is not possible to directly control or fix the potentials of the light blocking films 12a and 12b. The transistors Tr1 to Tr3 and Tr5 to Tr8 do not include the light blocking films 12a and 12b.

### Timing Chart

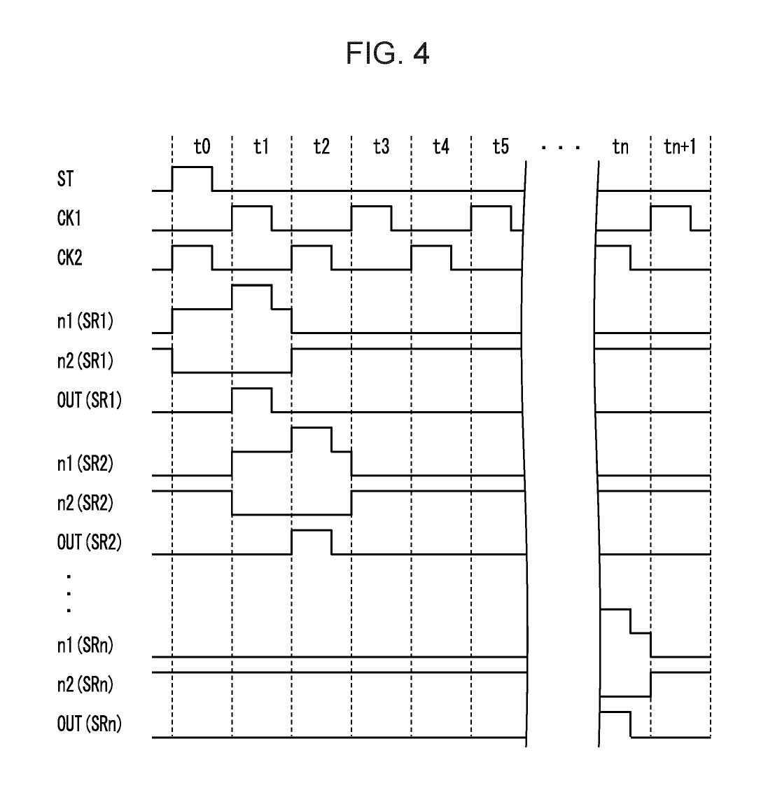

FIG. 4 is a timing chart illustrating a normal operation of the shift register 10 according to the first embodiment. The shift register 10 may carry out initialization when the initialization signal INIT is at a high level and carry out a normal operation when the initialization signal INIT is at a low level. Since the initialization signal INIT is at a low level during the normal operation, the transistor Tr7 may be turned off. Therefore, the transistor Tr7 does not affect the normal operation of the shift register 10.

During the normal operation, the clock signal CK1 may vary between a high level and a low level in a predetermined cycle. The high level period of the clock signal CK1 may be shorter than a half cycle. The clock signal CK2 may be a signal that is delayed from the clock signal CK1 by a half cycle. The start signal ST may be at a high level during the high-level period of the clock signal CK2 in a period t0.

In the period t0, the start signal ST input to the unit circuit 11 of the first stage may change to a high level. Therefore, the transistor Tr3 may be turned on, and the potential of the node n1 may be precharged to approximately (VDD−Vth). Upon the potential of the node n1 exceeding the on-level of the transistors at some point, the transistor Tr1 may be turned on. At this point, the clock signal CK1 may be at a low level, and thus the output signal OUT remains at a low level.

Upon the start signal ST changing to a high level, the transistor Tr5 may be turned on. At this point, the clock signal CK2 may be at a high level, and thus the transistor Tr6 may also be turned on. Since the resistor R1 is provided between the source electrode of the transistor Tr6 and the node n2, upon the transistors Tr5 and Tr6 both being turned on, the potential of the node n2 changes to a potential close to the low-level potential VSS (an off potential of a transistor). Therefore, the transistors Tr2 and Tr4 may be turned off. The start signal ST may change to a low level in a second half of the period t0. Therefore, the transistors Tr3 and Tr5 may be turned off. Thereafter, the node n1 may be retained at a high-level potential in a floating state.

In a period t1, the clock signal CK1 may change to a high level. At this point, the transistor Tr1 may be in an on state, and thus the potential of the output terminal OUT may rise, and the output signal OUT may enter a high level. In association therewith, the potential of the node n1 that is in a floating state may be boosted up via the capacitor C1 and the parasitic capacitance of the transistor Tr1, and thus the potential of the node n1 may rise to close to (2=VDD−Vth) (bootstrap operation). Since the potential of the node n1 exceeds (VDD+Vth), the potential of the output terminal OUT may become equal to the high-level potential VDD of the clock signal CK1 (a high-level potential with no threshold voltage drop). At this point, the transistor Tr8 may be turned on, and this makes it possible to reliably fix the potential of the node n2 at the low-level potential VSS. The clock signal CK1 may change to a low level in a second half of the period t1. Therefore, the output signal OUT may enter a low level, the potential of the node n1 may return to the potential (VDD−Vth) that is the same as the potential thereof in the period t0, and the transistor Tr8 may be turned off.

In a period t2, the clock signal CK2 may change to a high level. Therefore, the transistor Tr6 may be turned on, and a high-level potential may thus be applied to the node n2. At this point, the transistor Tr5 may be in an off state, and thus the potential of the node n2 may be at (VDD−Vth). Therefore, the transistor Tr4 may be turned on, and the potential of the node n1 may thus enter a low level, and the transistor Tr1 may be turned off. Upon the potential of the node n2 exceeding the on-level of the transistors at some point, the transistor Tr2 may be turned on, and thus the output signal OUT may be fixed again at a low level.

The clock signal CK2 may change to a low level in a second half of the period t2. Therefore, the transistor Tr6 may be turned off. Thereafter, during the high-level period of the clock signal CK2, the transistor Tr6 may be turned on, and thus a high-level potential may be applied to the node n2. During the low-level period of the clock signal CK2, the node n2 may be retained at a high-level potential in a floating state. In this manner, the output signal OUT of the unit circuit 11 of the first stage may enter a high level (the potential is VDD) during the high-level period of the clock signal CK1 in the period t1.

The output signal OUT of the unit circuit 11 of the first stage may be supplied to the input terminal IN of the unit circuit 11 of the second stage. During the periods t1 to t3, the unit circuit 11 of the second stage may operate similarly to the manner in which the unit circuit 11 of the first stage operates during the periods t0 to t2. The output signal OUT of the unit circuit 11 of the second stage may be supplied to the input terminal IN of the unit circuit 11 of the third stage. During the periods t2 to t4, the unit circuit 11 of the third stage may operate similarly to the manner in which the unit circuit 11 of the first stage operates during the periods t0 to t2. The n unit circuits 11 may successively operate similarly with a delay of a half cycle each of the clock signal CK1. Accordingly, the output signals GOUT1 to GOUTn of the shift register 10 may successively enter a high level for a duration that is equal to the duration of the high-level period of the clock signal CK1 with a delay of a half cycle each of the clock signal CK1.

In other words, the unit circuit 11 of the second stage may precharge the node n1 in the period t1 as the output signal OUT of the unit circuit 11 of the first stage is input to the input terminal IN of the unit circuit 11 of the second stage. The unit circuit 11 of the second stage may output the output signal OUT in the period t2. In the period t3, as the clock signal CK1 is input to the clock terminal CKB of the unit circuit 11 of the second stage, the unit circuit 11 of the second stage may discharge the node n1 and discharge the output signal OUT. The unit circuit 11 of the third stage to the unit circuit 11 of the final stage may each carry out these operations, and thus the shift register 10 that uses, as input signals, only the clock signals CK1 and CK2 and the output signal OUT of the unit circuit 11 of the previous stage can be achieved.

When the unit circuit 11 is to be initialized, the initialization signal INIT may change to a high level. At this point, the transistor Tr7 may be turned on, and the potential of the node n2 may become (VDD−Vth). Therefore, the transistor Tr4 may be turned on, the potential of the node n1 may enter a low level, and the transistor Tr1 may be turned off. In addition, the transistor Tr2 may be turned on, and the output signal OUT may enter a low level.

The unit circuit 11 may operate similarly to the manner described above even when the unit circuit 11 does not include the transistor Tr8. However, the unit circuit 11 that does not include the transistor Tr8 may be more likely to be affected by noise when the node n2 is in a floating state.

### Transistor Tr

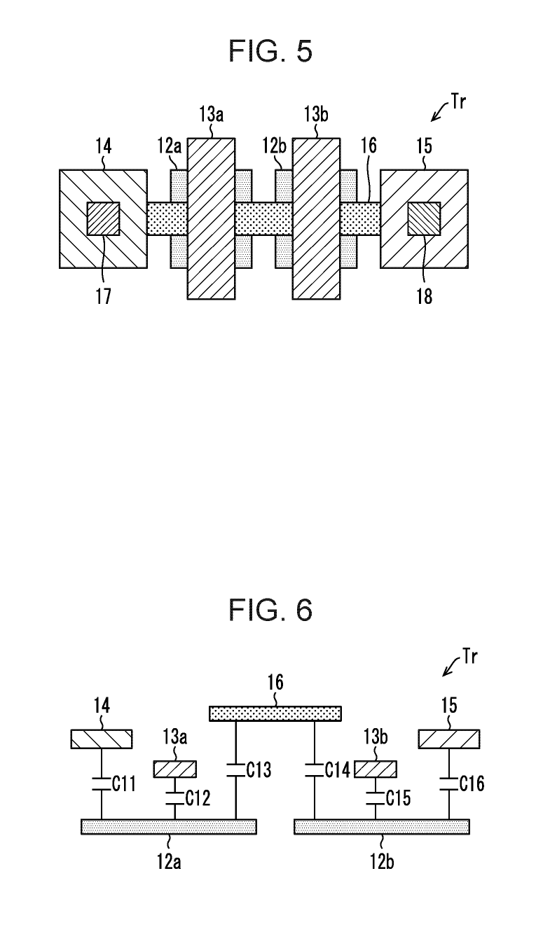

FIG. 5 illustrates a configuration of a transistor Tr according to the first embodiment. The transistor Tr is formed by laminating successively, from the bottom layer, a light blocking film layer, a semiconductor layer, a gate layer, and a source layer. The semiconductor layer is formed, for example, of polysilicon.

The transistor Tr includes light blocking films 12a and 12b, gate electrodes 13a and 13b (control electrode), a source electrode 14 (second conducting electrode), a drain electrode 15 (first conducting electrode), and a semiconductor portion 16. The light blocking films 12a and 12b are formed in the light blocking film layer, the semiconductor portion 16 is formed in the semiconductor layer, the gate electrodes 13a and 13b are formed in the gate layer, and the source electrode 14 and the drain electrode 15 are formed in the source layer.

The source electrode 14 and the drain electrode 15 are formed with a predetermined gap provided therebetween. The semiconductor portion 16 is formed between the source electrode 14 and the drain electrode 15. The gate electrodes 13a and 13b are formed between the source electrode 14 and the drain electrode 15 so as to overlap the semiconductor portion 16 as viewed in a plan view. The portion of the semiconductor portion 16 that overlaps the gate electrode 13a or 13b as viewed in a plan view serves as a channel portion (a portion where a channel is formed) of the transistor Tr. The light blocking film 12a and the light blocking film 12b are formed with a predetermined distance provided therebetween. The gate electrode 13a and the gate electrode 13b are formed with a predetermined distance provided therebetween. The light blocking film 12a and the gate electrode 13a overlap each other as viewed in a plan view, and the light blocking film 12b and the gate electrode 13b overlap each other as viewed in a plan view. The source electrode 14 and the semiconductor portion 16 are electrically coupled to each other via a contact hole 17. The drain electrode 15 and the semiconductor portion 16 are electrically coupled to each other via a contact hole 18.

In the unit circuit 11 illustrated in FIG. 3, the transistor Tr4 may be the transistor Tr that includes the light blocking films 12a and 12b. The other transistors Tr1 to Tr3 and Tr5 to Tr8 do not include the light blocking films 12a and 12b.

### Equivalent Circuit of Transistor Tr

FIG. 6 is a schematic diagram illustrating an equivalent circuit of the transistor Tr according to the first embodiment. As illustrated in FIG. 6, capacitors C11 to C16 are formed in the transistor Tr. Specifically, as the light blocking film 12a and the source electrode 14 overlap each other as viewed in a plan view, the capacitor C11 is formed between the light blocking film 12a and the source electrode 14. As the light blocking film 12a and the gate electrode 13a overlap each other as viewed in a plan view, the capacitor C12 is formed between the light blocking film 12a and the gate electrode 13a. As the light blocking film 12a and the semiconductor portion 16 overlap each other as viewed in a plan view, the capacitor C13 is formed between the light blocking film 12a and the semiconductor portion 16. As the light blocking film 12b and the semiconductor portion 16 overlap each other as viewed in a plan view, the capacitor C14 is formed between the light blocking film 12b and the semiconductor portion 16. As the light blocking film 12b and the gate electrode 13b overlap each other as viewed in a plan view, the capacitor C15 is formed between the light blocking film 12b and the gate electrode 13b. As the light blocking film 12b and the drain electrode 15 overlap each other as viewed in a plan view, the capacitor C16 is formed between the light blocking film 12b and the drain electrode 15.

In the driving example of the shift register 10 illustrated in FIG. 4, the gate potential of the transistor Tr4 may be at a high-level potential. Thus, a positive bias may be supplied to the gate potential of the transistor Tr4 for an extended period of time (or constantly), and thus the threshold voltage may shift due to an optical shift. Since the transistor Tr4 includes the light blocking films 12a and 12b, however, a shift in the threshold voltage caused by an optical shift can be suppressed, and thus a malfunction of the shift register 10 can be suppressed.

In the transistor Tr, a gate electrode 13 is divided into the gate electrode 13a and the gate electrode 13b. The withstanding voltage characteristics of the transistor Tr may be determined by the gate length (L length), and thus the withstanding voltage characteristics of the transistor Tr can be increased to a sufficient level if the total gate length in the transistor Tr can be extended to a sufficient level. A light blocking film 12 is divided into the light blocking films 12a and 12b so as to correspond to the division of the gate electrode.

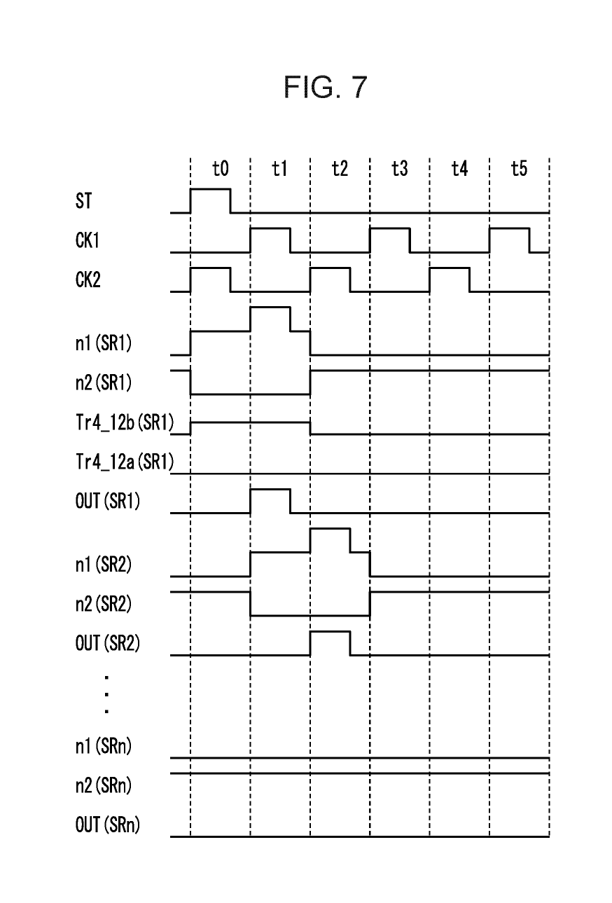

FIG. 7 is a timing chart illustrating a normal operation of the shift register 10 in a case in which the transistor Tr4 included in the unit circuit 11 according to the first embodiment includes the light blocking films 12a and 12b. In the unit circuit 11 illustrated in FIG. 3, the source electrode 14 of the transistor Tr4 may be coupled to the node n1, and the low-level potential VSS may be applied fixedly to the drain electrode 15 of the transistor Tr4. In the unit circuit 11 (SR1) of the first stage, when the node n1 is at a high-level potential, the light blocking film 12a of the transistor Tr4 may be in a floating state. At this point, since the light blocking film 12b of the transistor Tr4 is coupled to the node n1, the potential of the light blocking film 12b may float at a high-level side upon being affected by the coupling of the capacitor C11. Meanwhile, since the light blocking film 12a of the transistor Tr4 is not coupled to the node n1, the potential of the light blocking film 12a may not be affected by the coupling of the capacitor C11 and may thus not float at a high-level side. Therefore, an effect in which the light blocking film 12a functions like a gate electrode (back-gate effect) may not occur in the transistor Tr4, and thus the node n1 may not open. As a result, the unit circuit 11 can be bootstrapped, and thus the potential of the output signal OUT of the unit circuit 11 may not drop. Accordingly, a malfunction of the shift register 10 can be suppressed.

As described thus far, in the present embodiment, the shift register 10 that does not malfunction can be achieved without adding an auxiliary capacitor to the transistor Tr4. Since there is no need to add an auxiliary capacitor to the transistor Tr4, the size of the transistor Tr4 can be reduced, and the size of the unit circuit 11 and the shift register 10 can also be reduced as a result.

### Comparative Example

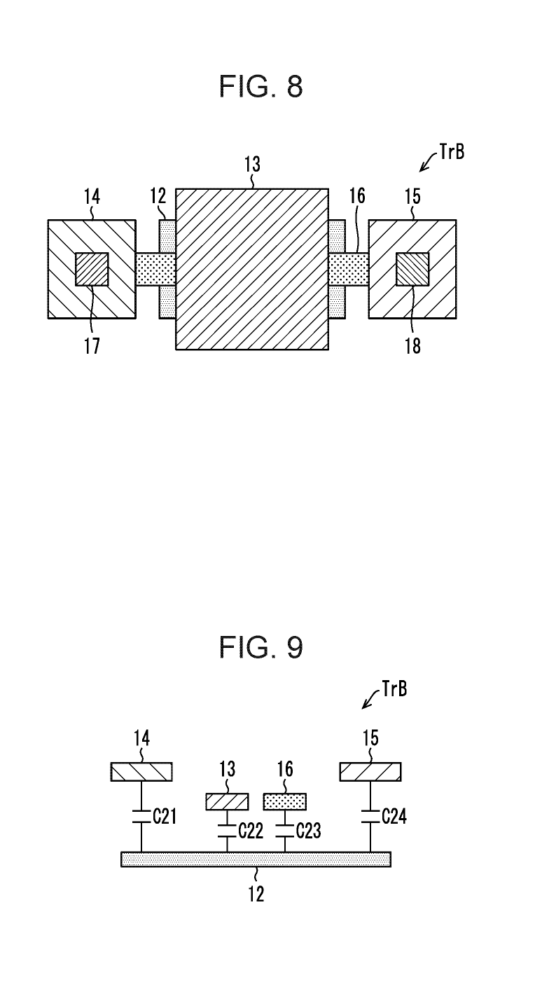

FIG. 8 illustrates a transistor TrB according to a comparative example. The transistor TrB illustrated in FIG. 8 includes a light blocking film 12, a gate electrode 13, a source electrode 14, a drain electrode 15, and a semiconductor portion 16. Unlike the transistor Tr illustrated in FIG. 5, neither the light blocking film 12 nor the gate electrode 13 is divided in the transistor TrB. In other words, the transistor TrB includes a single light blocking film 12 and a single gate electrode 13.

FIG. 9 illustrates an equivalent circuit of the transistor TrB according to the comparative example. Capacitors C21 to C24 are formed in the transistor TrB illustrated in FIG. 9. Specifically, as the light blocking film 12 and the source electrode 14 overlap each other as viewed in a plan view, the capacitor C21 is formed between the light blocking film 12 and the source electrode 14. As the light blocking film 12 and the gate electrode 13 overlap each other as viewed in a plan view, the capacitor C22 is formed between the light blocking film 12 and the gate electrode 13. As the light blocking film 12 and the semiconductor portion 16 overlap each other as viewed in a plan view, the capacitor C23 is formed between the light blocking film 12 and the semiconductor portion 16. As the light blocking film 12 and the drain electrode 15 overlap each other as viewed in a plan view, the capacitor C24 is formed between the light blocking film 12 and the drain electrode 15.

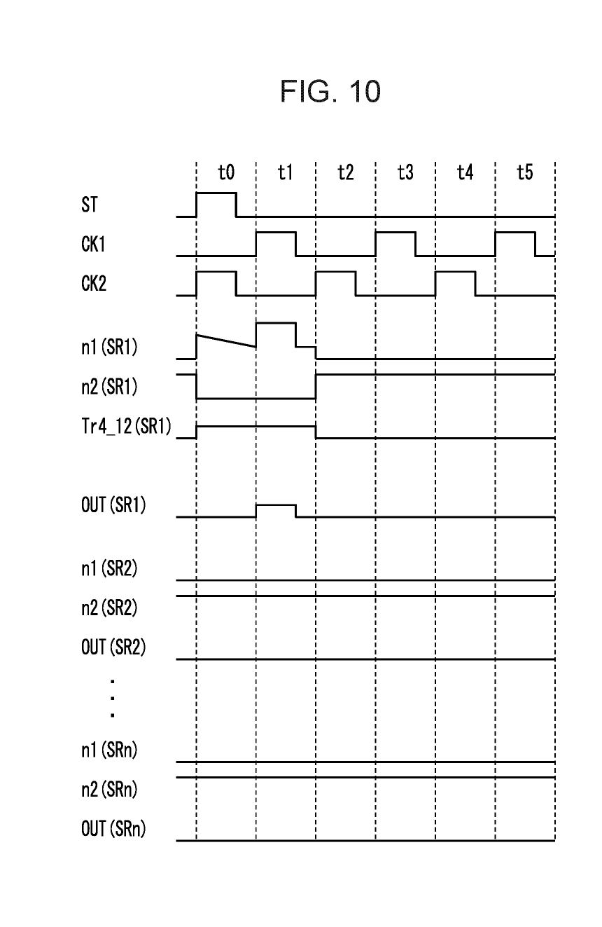

FIG. 10 is a timing chart illustrating a normal operation of a shift register 10 in a case in which a transistor Tr4 included in a unit circuit 11 according to the comparative example does not include the light blocking films 12a and 12b. In the example illustrated in FIG. 10, the transistor Tr4 included in the unit circuit 11 has a configuration identical to that of the transistor TrB illustrated in FIG. 8. The source electrode 14 of the transistor Tr4 is coupled to a node n1, and a low-level potential VSS is applied fixedly to the drain electrode 15 of the transistor Tr4. In the unit circuit 11 (SR1) of the first stage, when the node n1 is at a high-level potential, the light blocking film 12 of the transistor Tr4 is in a floating state. Therefore, the potential of the light blocking film 12 floats at a high-level side upon being affected by the coupling of the capacitor C21. At this point, the back-gate effect occurs in the transistor Tr4; thus, the transistor Tr4 enters a half-on state, and the node n1 opens. As a result, the unit circuit 11 cannot be bootstrapped, and thus the potential of the output signal OUT of the unit circuit 11 drops.

On the basis of the operation of the shift register 10 described above, the transistors Tr1 to Tr8 in the unit circuit 11 can be classified into two groups (a first group and a second group) in accordance with an on-duty. For example, one or more transistors that have the on/off state thereof controlled with a relatively high on-duty (no lower than 50 percent) can be classified into the first group, and one or more transistors that have the on/off state thereof controlled with a relatively low on-duty (lower than 50 percent) can be classified into the second group. Then, the transistors Tr2 and Tr4 may be classified in the first group, and the transistors Tr1, Tr3, and Tr5 to Tr8 may be classified into the second group. In the present embodiment, of the transistors included in the first group, as described above, only the transistor Tr4 may include the light blocking films 12a and 12b.

According to the present embodiment, of the eight transistors Tr1 to Tr8 provided in each unit circuit 11, only a portion of the transistors (i.e., the transistor Tr4) may include the light blocking films 12a and 12b. Since none of the transistors Tr1 to Tr3 and Tr5 to Tr8 includes the light blocking films 12a and 12b, a malfunction traceable to an off-leak in the transistors Tr1 to Tr3 and Tr5 to Tr8 may not occur. In addition, unlike a case in which the transistors Tr1 to Tr8 each include the light blocking films 12a and 12b, an unnecessary load (capacitance) between wires may not increase in the shift register 10 according to the present embodiment. Accordingly, a malfunction that could occur in a case in which the transistors Tr1 to Tr8 each include the light blocking films 12a and 12b may not occur in the shift register 10 according to the present embodiment.

### Second Embodiment

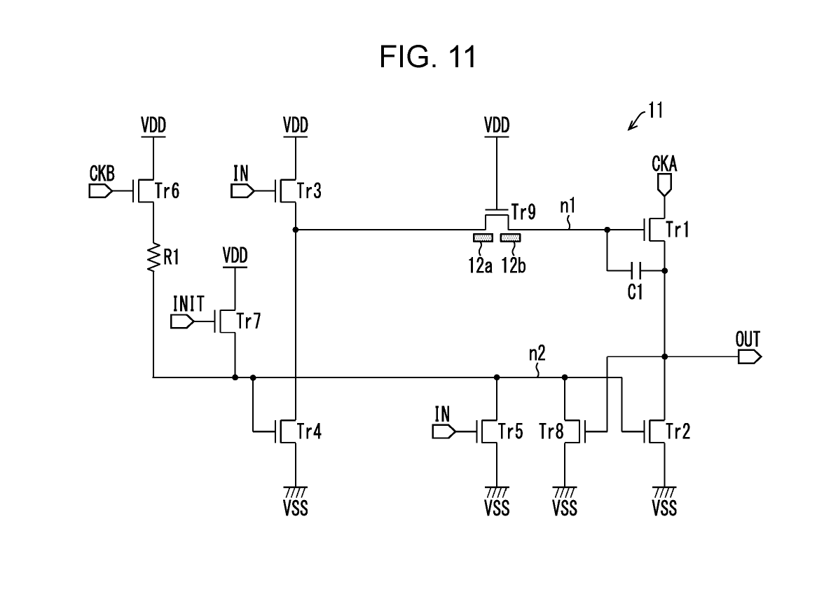

FIG. 11 is a configuration diagram of a unit circuit 11 according to a second embodiment. The unit circuit 11 illustrated in FIG. 11 is one of the plurality of unit circuits 11 constituting a shift register 10. In the present embodiment, configurations of a liquid crystal display device 1 and of the shift register 10 are identical to those of the foregoing embodiment. The unit circuit 11 illustrated in FIG. 11 may include nine transistors Tr1 to Tr9, a capacitor C1, and a resistor R1. The transistors Tr1 to Tr9 may each be an n-channel TFT.

In the present embodiment, the arrangement and the coupling of the transistors Tr1 to Tr8, the capacitor C1, and the resistor R1 in the unit circuit 11 are basically identical to those in the unit circuit 11 according to the first embodiment. In the present embodiment, a high-level potential VDD may be applied fixedly to a gate electrode of the transistor Tr9. A source electrode of the transistor Tr9 may be coupled to the source electrode of the transistor Tr3 and the drain electrode of the transistor Tr4. The drain electrode of the transistor Tr4 may be coupled to a node n1 via the transistor Tr9. A drain electrode of the transistor Tr9 may be coupled to the gate electrode of the transistor Tr1 and the capacitor C1. Unlike the unit circuit 11 illustrated in FIG. 3, the gate electrode of the transistor Tr1 may be coupled to neither the source electrode of the transistor Tr3 nor the drain electrode of the transistor Tr4.

In the present embodiment, none of the transistors Tr1 to Tr8 may include light blocking films 12a and 12b. Meanwhile, the transistor Tr9 may have a configuration identical to that of the transistor Tr illustrated in FIG. 5. In other words, the transistor Tr9 may include the light blocking films 12a and 12b and gate electrodes 13a and 13b.

In the present embodiment, an output control transistor may be implemented by the transistor Tr1, an output node turn-off transistor may be implemented by the transistor Tr2, a first node turn-off transistor may be implemented by the transistor Tr4, a voltage dividing transistor may be implemented by the transistor Tr9, and a first node turn-on unit may be implemented by the transistor Tr3, the input terminal IN, and an input terminal VDD for a high-level potential VDD. The first node turn-on unit may have a role of changing the level of the node n1 toward an on level in accordance with the output signal OUT output from the output terminal OUT of the unit circuit 11 of another stage.

While the shift register 10 according to the present embodiment is in a normal operation, the gate potential of the transistor Tr9 may be at a high-level potential. Therefore, a positive bias may be supplied to the gate potential of the transistor Tr9 for an extended period of time, and thus the threshold voltage may shift due to an optical shift. Since the transistor Tr9 includes the light blocking films 12a and 12b, however, a shift in the threshold voltage caused by an optical shift can be suppressed, and a malfunction of the shift register 10 can thus be suppressed. Furthermore, since there is no need to add an auxiliary capacitor to the transistor Tr9, the size of the transistor Tr9 can be reduced, and the size of the unit circuit 11 and the shift register 10 can also be reduced as a result.

The transistor Tr9 may be classified into the first group. According to the present embodiment, of the nine transistors Tr1 to Tr9 provided in each unit circuit 11, only a portion of the transistors (i.e., the transistor Tr9) may include the light blocking films 12a and 12b. Since none of the transistors Tr1 to Tr8 includes the light blocking films 12a and 12b, a malfunction traceable to an off-leak in the transistors Tr1 to Tr8 may not occur. In addition, unlike a case in which the transistors Tr1 to Tr9 each include the light blocking films 12a and 12b, an unnecessary load (capacitance) between wires may not increase in the shift register 10 according to the present embodiment. Accordingly, a malfunction that could occur in a case in which the transistors Tr1 to Tr9 each include the light blocking films 12a and 12b may not occur in the shift register 10 according to the present embodiment.

### Third Embodiment

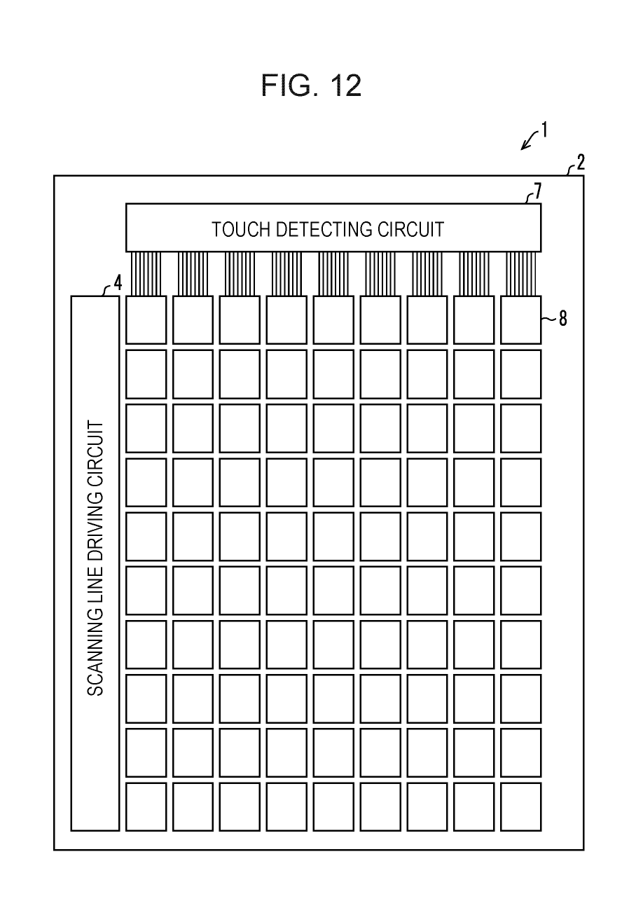

FIG. 12 is a block diagram illustrating a configuration of a liquid crystal display device 1 that includes a scanning line driving circuit 4 according to a third embodiment. The liquid crystal display device 1 illustrated in FIG. 12 may include a liquid crystal panel 2, a display controlling circuit 3, the scanning line driving circuit 4, a data line driving circuit 5, and a touch detecting circuit 7. In FIG. 12, illustration of the display controlling circuit 3, the data line driving circuit 5, and a pixel circuit 6 is omitted.

In the present embodiment, a common electrode constituting the pixel circuit 6 may be divided into a plurality of segment electrodes 8 that are disposed in a matrix. The plurality of segment electrodes 8 may each be coupled to the touch detecting circuit 7. Thus, the liquid crystal display device 1 may have a function of a segment in-cell touch panel. The liquid crystal display device 1 may determine whether the screen is being touched by a user with the use of the touch detecting circuit 7 and the segment electrodes 8.

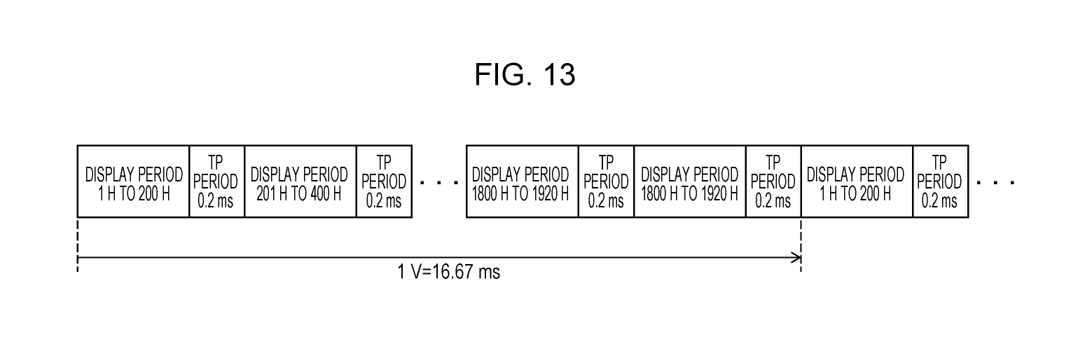

FIG. 13 illustrates details of one vertical interval held when the liquid crystal display device 1 according to the third embodiment operates. In FIG. 13, 1H denotes a single horizontal interval, 1V denotes a single vertical interval, and a TP period denotes a period for detecting a user's touch. As illustrated in FIG. 13, in the present embodiment, one TP period may be interposed between different display periods that are for displaying information on the liquid crystal panel 2. In FIG. 13, one vertical interval may be 16.67 ms, one display period may include 1 to 200 horizontal intervals, and one TP period is 0.2 ms. These values are merely examples.

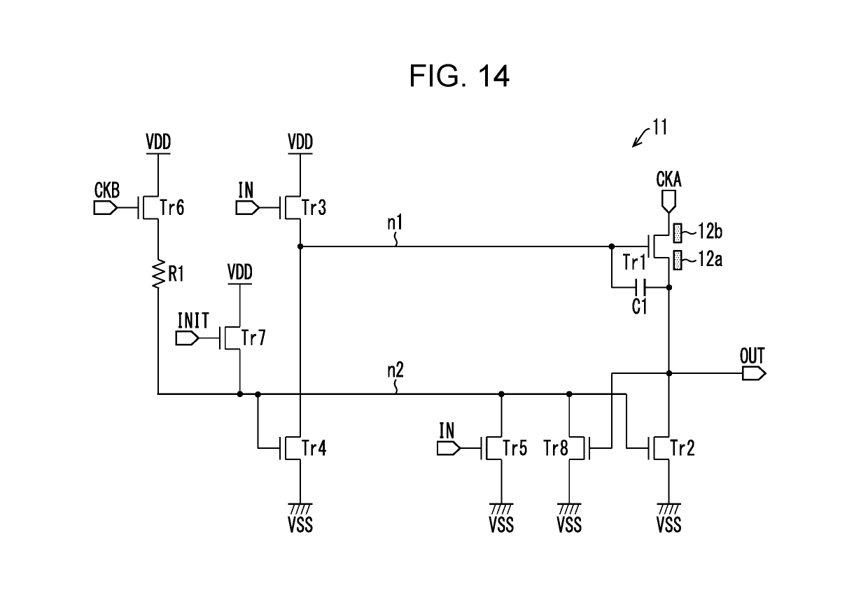

FIG. 14 is a circuit diagram of a unit circuit 11 according to the third embodiment. The unit circuit 11 illustrated in FIG. 14 may be one of a plurality of unit circuits 11 constituting a shift register 10. The unit circuit 11 illustrated in FIG. 14 may include eight transistors Tr1 to Tr8, a capacitor C1, and a resistor R1. The transistors Tr1 to Tr8 may each be an n-channel TFT. In the present embodiment, the arrangement and the coupling of the transistors Tr1 to Tr8, the capacitor C1, and the resistor R1 in the unit circuit 11 may be identical to those in the unit circuit 11 according to the first embodiment.

In the present embodiment, the transistors Tr2 to Tr8 may not include light blocking films 12a and 12b. Meanwhile, the transistor Tr1 may have a configuration identical to that of the transistor Tr illustrated in FIG. 5. In other words, the transistor Tr1 may include the light blocking films 12a and 12b and gate electrodes 13a and 13b.

In the present embodiment, a node n1 may be at a high-level potential only when the unit circuit 11 of the same stage is precharged and provides an output and may be at a low-level potential during the rest of the periods. Therefore, a negative bias may be supplied to the gate potential of the transistor Tr1 for an extended period of time (or constantly), and thus the threshold voltage may shift due to an optical shift.

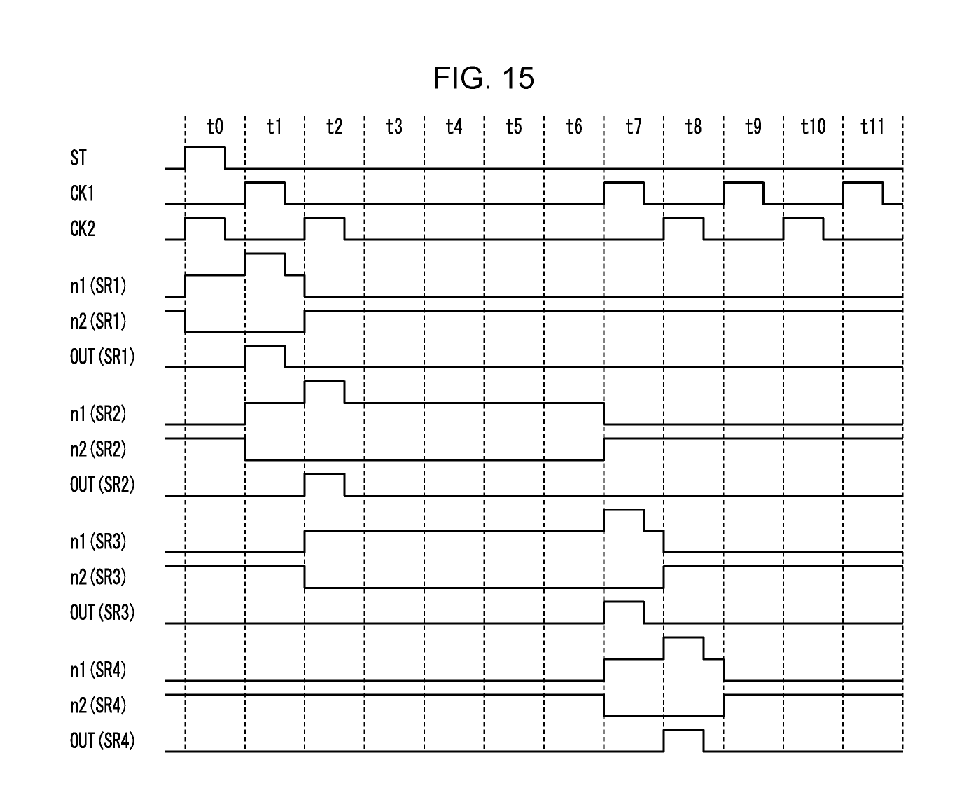

FIG. 15 is a timing chart illustrating a normal operation of the shift register 10 according to the third embodiment. In the liquid crystal display device 1 according to the present embodiment, a non display period may need to be provided during a scan of the liquid crystal panel 2 in order to detect a touch. In FIG. 15, the non display period may correspond to the periods t3 to t6 in which the output of clock signals CK1 and CK2 is being stopped. In a case in which the liquid crystal display device 1 is driven such that the scan of the liquid crystal panel 2 is stopped in midstream, an on-stress time applied to the transistor Tr1 may differ in different gate lines GL. Therefore, the amount of deterioration in a write voltage may differ between the adjacent gate lines GL, and thus a streak may appear in the liquid crystal panel 2. However, since the transistor Tr1 includes the light blocking films 12a and 12b, a shift in the threshold voltage caused by the optical shift can be suppressed, and thus an occurrence of a streak in the liquid crystal panel 2 can be suppressed. In addition, since there is no need to add an auxiliary capacitor to the transistor Tr1, the size of the transistor Tr1 can be reduced, and the size of the unit circuit 11 and the shift register 10 can also be reduced as a result.

In the present embodiment, of the transistors included in the second group, only a portion of the transistors (i.e., the transistor Tr1) may include the light blocking films 12a and 12b. Since the transistors Tr2 to Tr8 may not include the light blocking films 12a and 12b, a malfunction traceable to an off-leak in the transistors Tr2 to Tr8 may not occur. In addition, unlike a case in which the transistors Tr1 to Tr8 each include the light blocking films 12a and 12b, an unnecessary load (capacitance) between wires may not increase in the shift register 10 according to the present embodiment. Accordingly, a malfunction that could occur in a case in which the transistors Tr1 to Tr8 each include the light blocking films 12a and 12b may not occur in the shift register 10 according to the present embodiment.

### Fourth Embodiment

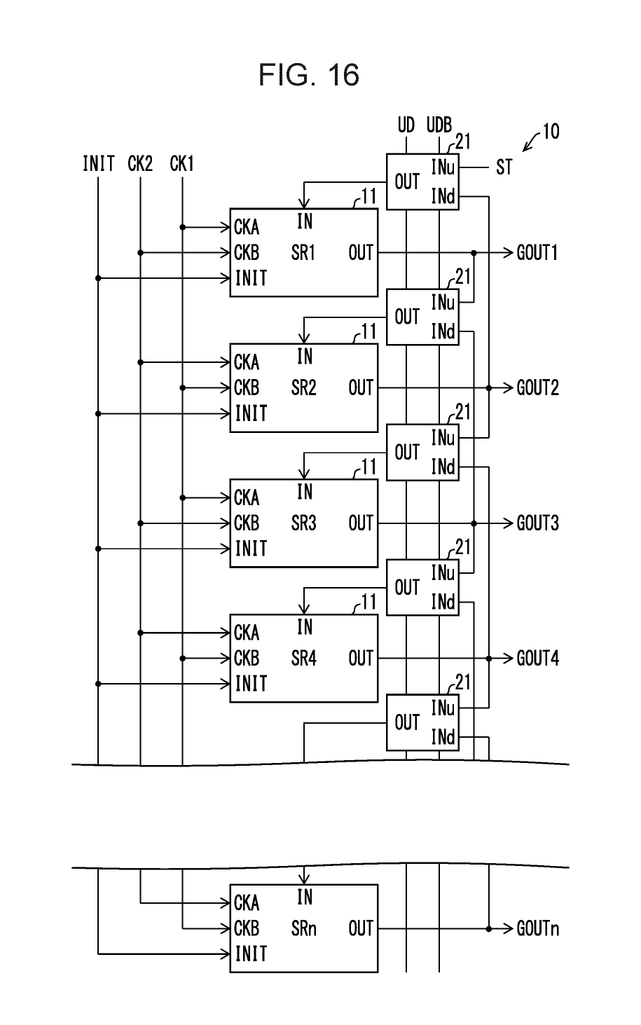

FIG. 16 is a block diagram illustrating a configuration of a shift register 10 included in a scanning line driving circuit 4 according to a fourth embodiment. An overall configuration of a liquid crystal display device 1 according to the present embodiment may be identical to that of the liquid crystal display device 1 according to the second embodiment, and thus descriptions thereof will be omitted. The shift register 10 illustrated in FIG. 16 may have a configuration in which n unit circuits 11 are coupled in cascade and n switching circuits 21 are coupled in cascade. The unit circuits 11 may each have a configuration identical to that of the unit circuit 11 according to the first embodiment. The switching circuits 21 may each include input terminals INu and INd and an output terminal OUT.

As illustrated in FIG. 16, a forward direction signal UD and a reverse direction signal UDB may be supplied to each of the switching circuits 21. The start signal ST may be supplied to the input terminal INu of the switching circuit 21 of the first stage. The output signal OUT of the switching circuit 21 of the first stage may be supplied to the input terminal IN of the unit circuit 11 of the first stage. The output signal OUT of the unit circuit 11 of the first stage may be output outside as an output signal GOUT1 and also supplied to the input terminal INu of the switching circuit 21 of the second stage. The output signal OUT of the switching circuit 21 of the second stage may be supplied to the input terminal IN of the unit circuit 11 of the third stage. The output signal OUT of the unit circuit 11 of the second stage may be output outside as an output signal GOUT2 and supplied to each of the input terminal INd of the switching circuit 21 of the first stage and the input terminal INu of the switching circuit 21 of the third stage.

In generalized terms, the output signal OUT of the switching circuit 21 of the kth stage (k is an integer no smaller than 1 nor greater than n) may be input to the input terminal IN of the unit circuit 11 of the kth stage. The output signal OUT of the unit circuit 11 of the jth stage (j is an integer no smaller than 2 and less than n) may be output outside as an output signal GOUTj and supplied to each of the input terminal INd of the switching circuit 21 of the (j−1)th stage and the input terminal INu of the switching circuit 21 of the (j+1)th stage. The output signal OUT of the unit circuit 11 of the nth stage may be output outside as an output signal GOUTn and also supplied to the input terminal INd of the switching circuit 21 of the (n−1)th stage.

The input patterns of the initialization signal INIT and the clock signals CK1 and CK2 into each unit circuit 11 may be identical to those of the first embodiment, and thus descriptions thereof will be omitted.

### Configuration Example of Switching Circuit 21

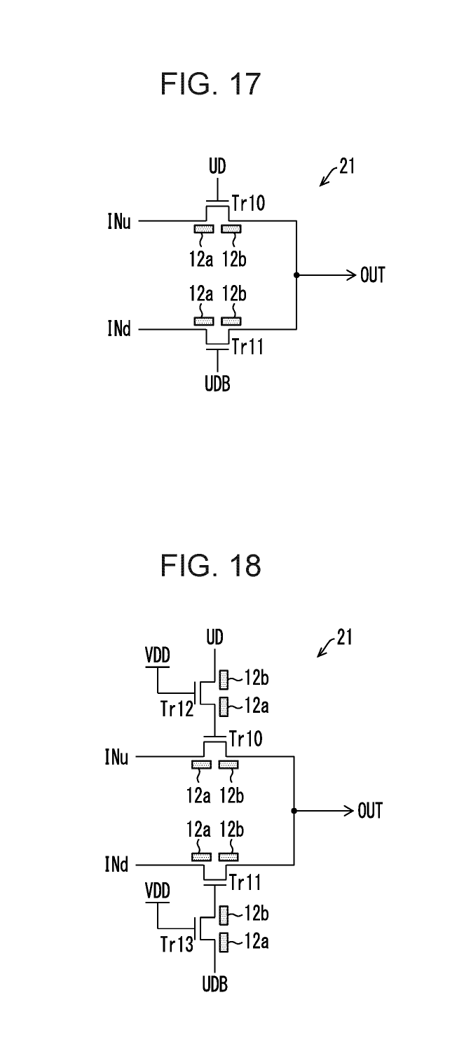

FIG. 17 illustrates a configuration example of the switching circuit 21 according to the fourth embodiment. In the example illustrated in FIG. 17, the switching circuit 21 may include transistors Tr10 and Tr11. The transistors Tr10 and Tr11 may each be the transistor Tr illustrated in FIG. 5. In other words, the transistors Tr10 and Tr11 may each include light blocking films 12a and 12b.

In the switching circuit 21 illustrated in FIG. 17, a drain electrode of the transistor Tr10 may be coupled to the input terminal INu. A gate electrode of the transistor Tr10 may be supplied with the forward direction signal UD. A source electrode of the transistor Tr10 may be coupled to the output terminal OUT and a source electrode of the transistor Tr11. A drain electrode of the transistor Tr11 may be coupled to the input terminal INd. A gate electrode of the transistor Tr11 may be supplied with the reverse direction signal UDB. The source electrode of the transistor Tr11 may be coupled to the output terminal OUT and the source electrode of the transistor Tr10.

FIG. 18 illustrates another configuration example of the switching circuit 21 according to the embodiment. In the example illustrated in FIG. 18, the switching circuit 21 may include transistors Tr10, Tr11, Tr12, and Tr13. The transistors Tr10 to Tr13 may each be the transistor Tr illustrated in FIG. 5. In other words, the transistors Tr10 to Tr13 may each include light blocking films 12a and 12b.

In the switching circuit 21 illustrated in FIG. 18, a drain electrode of the transistor Tr10 may be coupled to the input terminal INu. A gate electrode of the transistor Tr10 may be coupled to a drain electrode of the transistor Tr12. A source electrode of the transistor Tr10 may be coupled to the output terminal OUT and a source electrode of the transistor Tr11. A drain electrode of the transistor Tr11 may be coupled to the input terminal INd. A gate electrode of the transistor Tr11 may be coupled to a source electrode of the transistor Tr13. A source electrode of the transistor Tr12 may be supplied with the forward direction signal UD, and the high-level potential VDD may be applied fixedly to a gate electrode of the transistor Tr12. A drain electrode of the transistor Tr13 may be supplied with the reverse direction signal UDB, and the high-level potential VDD may be applied fixedly to a gate electrode of the transistor Tr13.

### Timing Chart

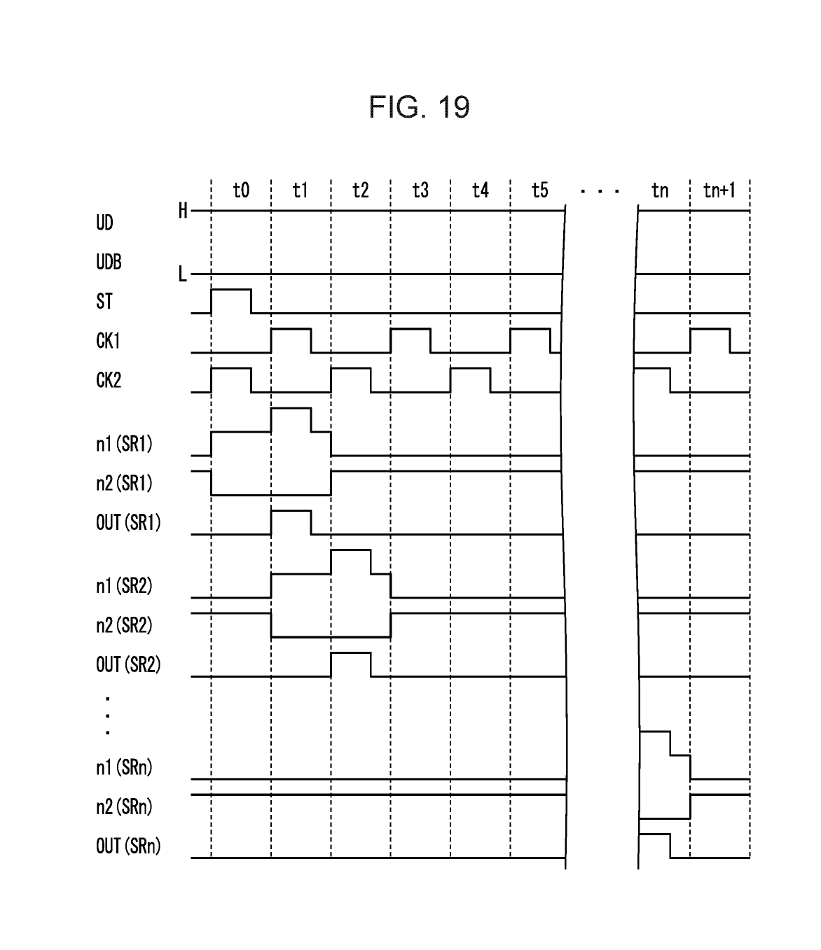

FIG. 19 is a timing chart illustrating a normal operation of the shift register 10 according to the fourth embodiment. The operation of each unit circuit 11 may be identical to that of the first embodiment, and thus detailed descriptions thereof will be omitted. In the example illustrated in FIG. 19, the forward direction signal UD of a high-level potential and the reverse direction signal UDB of a low-level potential may keep being supplied to each switching circuit 21. Thus, the transistor Tr10 may stay in an on state, and the transistor Tr11 may stay in an off state. In this case, of the signal input to the input terminal INu and the signal input to the input terminal INd, the signal input to the input terminal INu may keep being output from the switching circuit 21 as the output signal OUT. Thus, the output signals OUT output from the respective unit circuits 11 may successively enter a high level in the order of “from the first stage to the nth stage.”

In contrast, in a case in which the forward direction signal UD of a low-level potential and the reverse direction signal UDB of a high-level potential keep being supplied to each switching circuit 21, the transistor Tr10 may stay in an off state, and the transistor Tr11 may stay in an on state. In this case, of the signal input to the input terminal INu and the signal input to the input terminal INd, the signal input to the input terminal INd may keep being output from the switching circuit 21 as the output signal OUT. Thus, the output signals OUT output from the respective unit circuits 11 may successively enter a high level in the order of “from the nth stage to the first stage.”

In a case in which each switching circuit 21 has a configuration illustrated in FIG. 17, in the driving example illustrated in FIG. 19, the gate potential of the transistor Tr10 may be retained at a high-level potential. Therefore, the gate electrode of the transistor Tr10 may keep being supplied with a bias, and thus the threshold voltage may shift due to an optical shift. Since the transistor Tr10 includes the light blocking films 12a and 12b, however, a shift in the threshold voltage caused by an optical shift can be suppressed, and thus a malfunction of the shift register 10 can be suppressed.

In a case in which each switching circuit 21 has a configuration illustrated in FIG. 18, in the driving example illustrated in FIG. 19, the gate potentials of the transistors Tr10, Tr12, and Tr13 may be retained at a high-level potential. Therefore, the transistors Tr10, Tr12, and Tr13 may keep being supplied with a bias, and thus the threshold voltage may shift due to an optical shift. Since the transistors Tr10, Tr12, and Tr13 each include the light blocking films 12a and 12b, however, a shift in the threshold voltage caused by an optical shift can be suppressed, and thus a malfunction of the shift register 10 can be suppressed.

### Fifth Embodiment

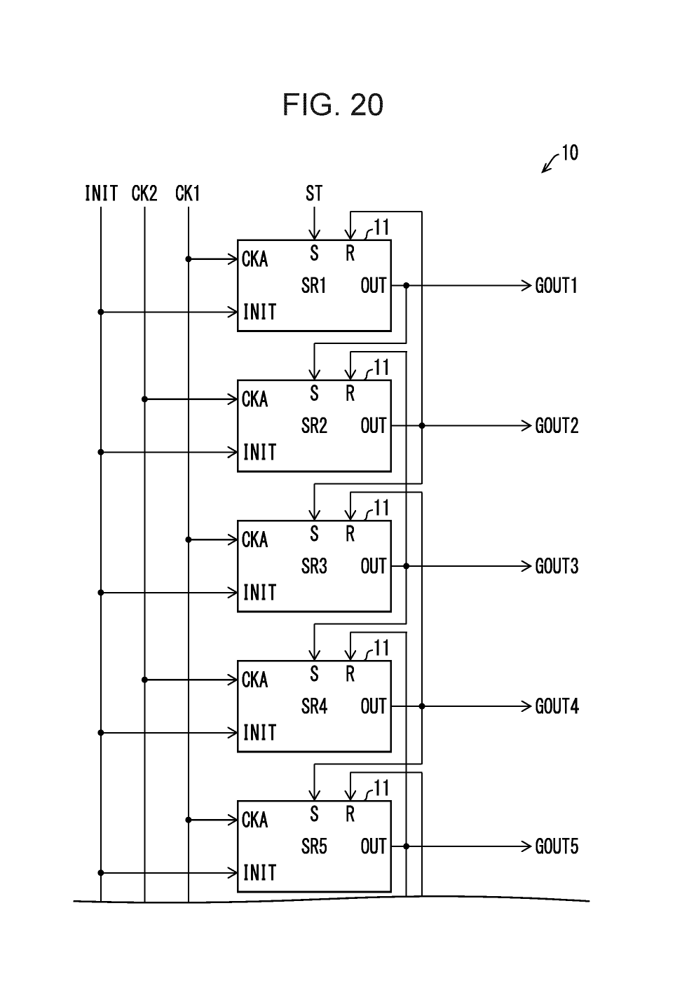

FIG. 20 is a block diagram illustrating a configuration of a shift register 10 included in a scanning line driving circuit 4 according to a fifth embodiment. An overall configuration of a liquid crystal display device 1 according to the present embodiment may be identical to that of the liquid crystal display device 1 according to the second embodiment, and thus descriptions thereof will be omitted. The shift register 10 illustrated in FIG. 20 may have a configuration in which n unit circuits 11 are coupled in cascade. The unit circuits 11 may each include a clock terminal CKA, input terminals S and R, an initialization terminal INIT, and an output terminal OUT.

As illustrated in FIG. 20, the start signal ST may be supplied to the input terminal S of the unit circuit 11 of the first stage. The clock signal CK1 may be supplied to the clock terminals CKA of the unit circuits 11 of the odd-number stages. The clock signal CK2 may be supplied to the clock terminals CKA of the unit circuits 11 of the even-number stages. The clock signals CK1 and CK2 may be controlled such that one of the clock signals CK1 and CK2 is at a high-level potential and the other one of them is at a low-level potential. The initialization signal INIT may be supplied to the initialization terminals INIT of the n unit circuits 11.

The output signal OUT of the unit circuit 11 of the first stage may be output outside as an output signal GOUT1 and also supplied to the input terminal S of the unit circuit 11 of the second stage. The output signal OUT of the unit circuit 11 of the second stage may be output outside as an output signal GOUT2 and also supplied to the input terminal R of the unit circuit 11 of the first stage and the input terminal S of the unit circuit 11 of the third stage. In generalized terms, the output signal OUT of the unit circuit 11 of the kth stage (k is an integer no smaller than 2 nor greater than n) may be output outside as an output signal GOUTk and also supplied to the input terminal R of the unit circuit 11 of the (k−1)th stage and the input terminal S of the unit circuit 11 of the (k+1)th stage. The output signal OUT of the unit circuit 11 of the nth stage may be output outside as an output signal GOUTn and also supplied to the input terminal R of the unit circuit 11 of the (n−1)th stage.

### Configuration Example of Unit Circuit 11

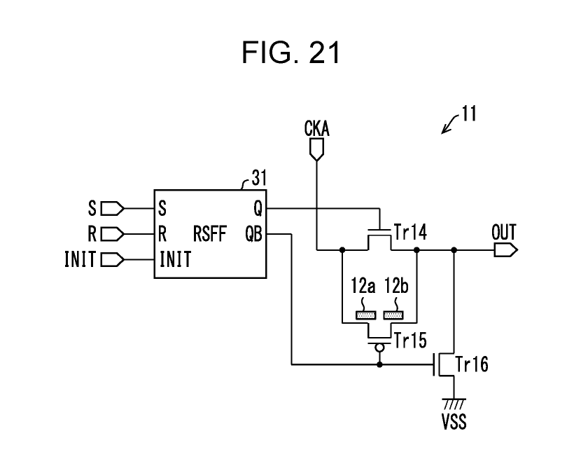

FIG. 21 illustrates a configuration of the unit circuit 11 according to the fifth embodiment. The unit circuit 11 illustrated in FIG. 21 may be an example of a CMOS circuit. The unit circuit 11 illustrated in FIG. 21 may include a set-reset flip-flop (RS flip-flop) 31 and transistors Tr14, Tr15, and Tr16. The transistors Tr14 and Tr15 may each be an n-channel TFT, and the transistor Tr15 may be a p-channel (second conductivity type) TFT. The transistors Tr14 and Tr15 may be included in the second group. The transistor Tr16 may be included in the first group. In the present embodiment, the transistors Tr14 and Tr16 may not include light blocking films 12a and 12b. Meanwhile, the transistor Tr15 may have a configuration identical to that of the transistor Tr illustrated in FIG. 5. In other words, only the transistor Tr15 may include the light blocking films 12a and 12b.

In the present embodiment, a first output control transistor may be implemented by the transistor Tr14, a second output control transistor may be implemented by the transistor Tr15, and an output node turn-off transistor may be implemented by the transistor Tr16.

The RS flip-flop 31 may include input terminals S and R, an initialization terminal INIT, and output terminals Q and QB. The input terminals S and R of the unit circuit 11 may be coupled to the respective input terminals S and R of the RS flip-flop 31. The initialization terminal INIT of the unit circuit 11 may be coupled to the initialization terminal INIT of the RS flip-flop 31.

A gate electrode of the transistor Tr14 may be coupled to the output terminal Q of the RS flip-flop 31. A source electrode of the transistor Tr14 may be coupled to the clock terminal CKA of the unit circuit 11 and a source electrode of the transistor Tr15. A drain electrode of the transistor Tr14 may be coupled to the output terminal OUT of the unit circuit 11, a drain electrode of the transistor Tr15, and a drain electrode of the transistor Tr16.

The source electrode of the transistor Tr15 may be coupled to the clock terminal CKA of the unit circuit 11 and the source electrode of the transistor Tr14. The drain electrode of the transistor Tr15 may be coupled to the output terminal OUT of the unit circuit 11, the drain electrode of the transistor Tr14, and the drain electrode of the transistor Tr16.

A gate electrode of the transistor Tr15 may be coupled to the output terminal QB of the RS flip-flop 31 and a gate electrode of the transistor Tr16. The low-level potential VSS may be applied fixedly to a source electrode of the transistor Tr16. The drain electrode of the transistor Tr16 may be coupled to the output terminal OUT of the unit circuit 11, the drain electrode of the transistor Tr14, and the drain electrode of the transistor Tr15.

### Timing Chart

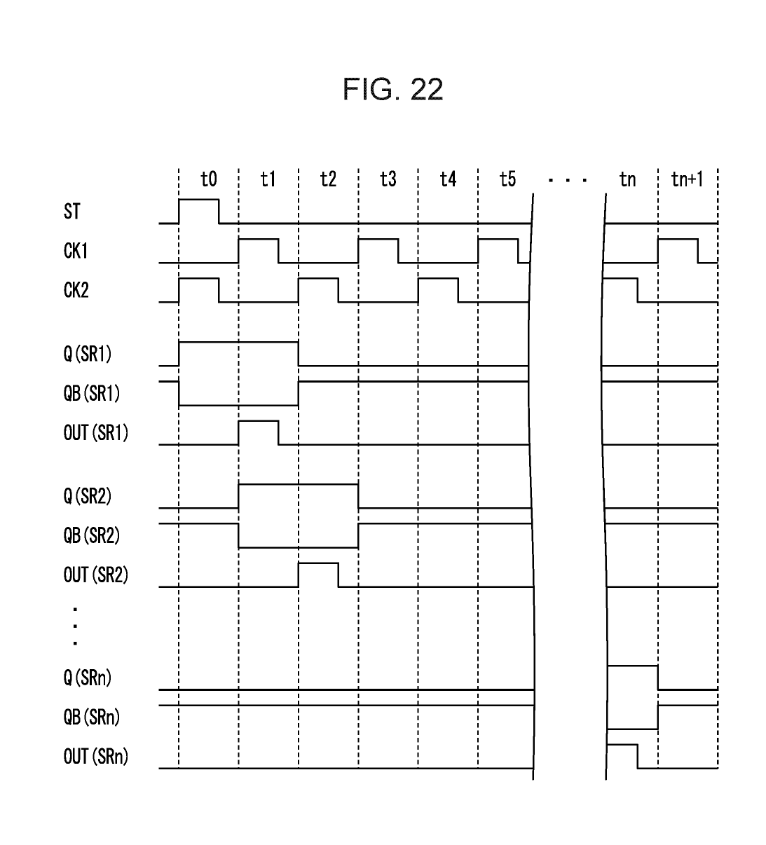

FIG. 22 is a timing chart illustrating a normal operation of the shift register 10 according to the fifth embodiment. With reference to FIG. 22, a normal operation of the shift register 10 carried out in a case in which VDD is a high-level potential, VSS is a low-level potential, and the start signal ST and the clock signal CK1 are input to the shift register 10 will be described.

In the period t0, the start signal ST of a high-level potential may be input to the input terminal S of the unit circuit 11 of the first stage. Thus, in the unit circuit 11 of the first stage, the RS flip-flop 31 may enter a set state. As a result, the high-level potential VDD (a first output signal) may be output from the output terminal Q of the RS flip-flop 31, and the low-level potential VSS (a second output signal) may be output from the output terminal QB of the RS flip-flop 31. In the period t1, the clock signal CK1 of a high-level potential may be input to the clock terminal CKA of the unit circuit 11. Thus, in the unit circuit 11 of the first stage, a pulsed output signal GOUT1 may be output outside via the transistors Tr14 and Tr15 and an output buffer.

In the period t2, the clock signal CK2 of a high-level potential may be input to the clock terminal CKA of the unit circuit 11 of the second stage, and thus the output signal GOUT2 may be output from the unit circuit 11 of the second stage. The output signal GOUT2 may be input to the input terminal R of the unit circuit 11 of the first stage. Thus, the RS flip-flop 31 of the unit circuit 11 of the first stage may enter a reset state. Therefore, in the unit circuit 11 of the first stage, the low-level potential VSS may be output from the output terminal Q of the RS flip-flop 31, and the high-level potential VDD may be output from the output terminal QB of the RS flip-flop 31. As a result, in the unit circuit 11 of the first stage, the transistor Tr16 may be turned on, and thus the output signal OUT can be pulled down reliably.

The unit circuit 11 of the second stage may operate similarly to the manner in which the unit circuit 11 of the first stage operates. In the period t1, the output signal GOUT1 may be input to the input terminal S of the unit circuit 11 of the second stage. Thus, the RS flip-flop 31 of the unit circuit 11 of the second stage may enter a set state. As a result, in the unit circuit 11 of the second stage, the high-level potential VDD may be output from the output terminal Q of the RS flip-flop 31, and the low-level potential VSS may be output from the output terminal QB of the RS flip-flop 31. In the period t2, the clock signal CK2 of a high-level potential may be input to the clock terminal CKA of the unit circuit 11 of the second stage. Thus, in the unit circuit 11 of the second stage, a pulsed output signal GOUT2 may be output outside via the transistors Tr14 and Tr15 and the output buffer.

In the period t3, the clock signal CK1 of a high-level potential may be input to the clock terminal CKA of the unit circuit 11 of the third stage, and thus the output signal GOUT3 may be output from the unit circuit 11 of the third stage. The output signal GOUT3 may be input to the input terminal R of the unit circuit 11 of the second stage. Thus, the RS flip-flop 31 of the second stage may be reset. Therefore, in the RS flip-flop 31 of the second stage, the low-level potential VSS may be output from the output terminal Q, and the high-level potential VDD may be output from the output terminal QB. As a result, in the unit circuit 11 of the second stage, the output signal OUT can be pulled down reliably.

The unit circuit 11 of the third stage to the unit circuit 11 of the final stage may each carry out the above-described operation, and thus the shift register 10 that uses, as input signals, only the clock signals CK1 and CK2 and the output signal OUT of the unit circuit 11 of the previous stage can be achieved.

In the unit circuit 11 illustrated in FIG. 21, the transistor Tr15 may be a large-sized transistor for driving the gate lines GL and may be a portion where an off-leak is suspected. In addition, since an output signal QB is supplied to the gate electrode of the transistor Tr15, a negative bias may be applied to the gate electrode of the transistor Tr15 for an extended period of time. In the present embodiment, since the transistor Tr15 includes the light blocking films 12a and 12b, an off-leak caused if the transistor Tr15 is irradiated with light can be suppressed, and a shift in the threshold associated with an influence of outside light onto the transistor Tr15 may be suppressed. Accordingly, a malfunction of the shift register 10 can be suppressed.

### Sixth Embodiment

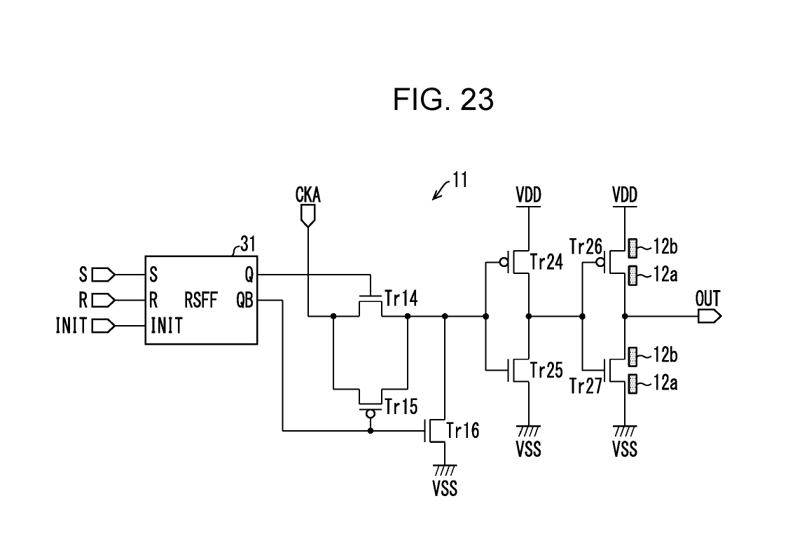

FIG. 23 illustrates a configuration example of a unit circuit 11 according to a sixth embodiment. The unit circuit 11 illustrated in FIG. 23 may be an example of a CMOS circuit. The unit circuit 11 illustrated in FIG. 23 may include input terminals S and R, an initialization terminal INIT, an RS flip-flop 31, transistors Tr14 to Tr16 and Tr24 to Tr27, and an output terminal OUT. In the present embodiment, the transistors Tr14, Tr16, Tr25, and Tr27 may each be an n-channel transistor, and the transistors Tr15, Tr24, and Tr26 may each be a p-channel transistor. The transistor Tr26 may be classified into the second group, and the transistor Tr27 may be classified into the first group.

In the present embodiment, the transistors Tr14 to Tr16, Tr24, and Tr25 may not include light blocking films 12a and 12b. Meanwhile, the transistors Tr26 and Tr27 may each have a configuration identical to that of the transistor Tr illustrated in FIG. 5. In other words, the transistors Tr26 and Tr27 may each include the light blocking films 12a and 12b.

The RS flip-flop 31 may include input terminals S and R, an initialization terminal INIT, and output terminals Q and QB. The input terminals S and R of the unit circuit 11 may be coupled to the respective input terminals S and R of the RS flip-flop 31. The initialization terminal INIT of the unit circuit 11 may be coupled to the initialization terminal INIT of the RS flip-flop 31. The output terminal Q of the RS flip-flop 31 may be coupled to a gate electrode of the transistor Tr14. The output terminal QB of the RS flip-flop 31 may be coupled to a gate electrode of the transistor Tr15 and a gate electrode of the transistor Tr16.

A source electrode of the transistor Tr14 may be coupled to the clock terminal CKA of the unit circuit 11 and a source electrode 14 of the transistor Tr15. A drain electrode of the transistor Tr14 may be coupled to a drain electrode 15 of the transistor Tr15, a drain electrode of the transistor Tr16, a gate electrode of the transistor Tr24, and a gate electrode of the transistor Tr25. The low-level potential VSS may be applied fixedly to a source electrode of the transistor Tr16.

The gate electrode of the transistor Tr24 may be coupled to the drain electrode of the transistor Tr14, the drain electrode of the transistor Tr15, the drain electrode of the transistor Tr16, and the gate electrode of the transistor Tr25. The high-level potential VDD may be applied fixedly to a drain electrode of the transistor Tr24. A source electrode of the transistor Tr24 may be coupled to a source electrode of the transistor Tr25, a gate electrode of the transistor Tr26, and a gate electrode of the transistor Tr27.

The gate electrode of the transistor Tr25 may be coupled to the drain electrode of the transistor Tr14, the drain electrode of the transistor Tr15, the drain electrode of the transistor Tr16, and the gate electrode of the transistor Tr24. The low-level potential VSS may be applied fixedly to a drain electrode of the transistor Tr25. The source electrode of the transistor Tr25 may be coupled to the source electrode of the transistor Tr24, the gate electrode of the transistor Tr26, and the gate electrode of the transistor Tr27.

The gate electrode of the transistor Tr26 may be coupled to the drain electrode of the transistor Tr24, the drain electrode of the transistor Tr25, and the gate electrode of the transistor Tr27. The high-level potential VDD may be applied fixedly to a drain electrode of the transistor Tr26. A source electrode of the transistor Tr26 may be coupled to a drain electrode of the transistor Tr27 and the output terminal OUT. The gate electrode of the transistor Tr27 may be coupled to the source electrode of the transistor Tr24, the drain electrode of the transistor Tr25, and the gate electrode of the transistor Tr26. The low-level potential VSS may be applied fixedly to a source electrode of the transistor Tr27. The drain electrode of the transistor Tr27 may be coupled to the source electrode of the transistor Tr26 and the output terminal OUT.

In the unit circuit 11 illustrated in FIG. 23, the transistors Tr26 and Tr27 may each be a large-sized transistor for driving the gate lines GL and may each be a portion where an off-leak is suspected. In addition, a positive bias may be applied to the gate electrode of the transistor Tr26 for an extended period of time. A negative bias may be applied to the gate electrode of the transistor Tr27 for an extended period of time. In the present embodiment, since the transistors Tr26 and Tr27 each include the light blocking films 12a and 12b, an off-leak caused if the transistors Tr26 and Tr27 are irradiated with light can be suppressed, and thus a malfunction of the shift register 10 can be suppressed.

### Seventh Embodiment

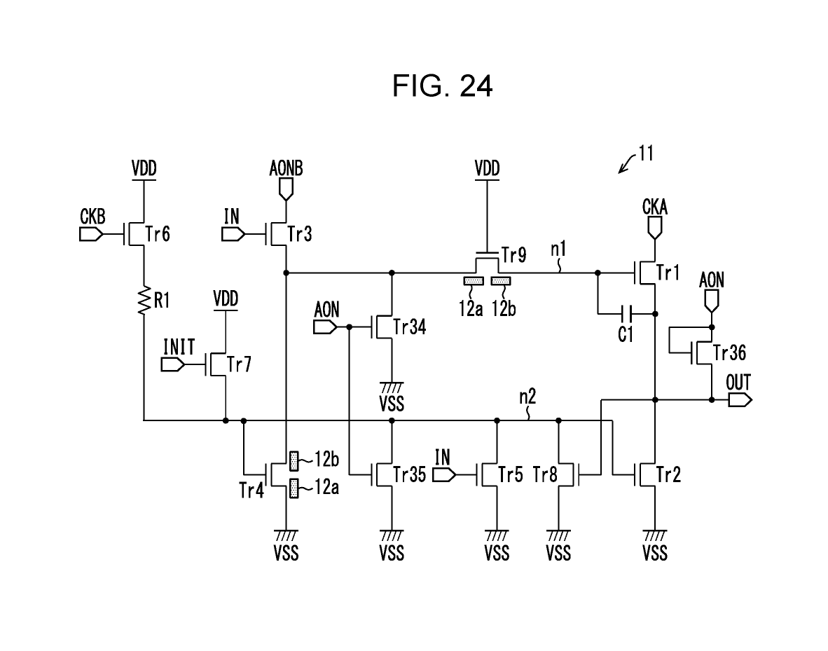

FIG. 24 illustrates a configuration example of a unit circuit 11 according to a seventh embodiment. The unit circuit 11 illustrated in FIG. 24 may be a circuit having a configuration in which an all-on control (AON) function is further added to a combination of the unit circuit 11 according to the first embodiment and the unit circuit 11 according to the second embodiment.

The unit circuit 11 illustrated in FIG. 24 may include transistors Tr1 to Tr9 and Tr34 to Tr36, a capacitor C1, and a resistor R1. The transistors Tr1 to Tr9 and Tr34 to Tr36 may each be an n-channel TFT.

In the unit circuit 11 according to the present embodiment, the arrangement and the coupling of the transistors Tr1 to Tr9, the capacitor C1, and the resistor R1 are basically identical to those in the unit circuit 11 according to the second embodiment. In the unit circuit 11 according to the present embodiment, a source electrode of the transistor Tr3 may be coupled to an input terminal AONB.

A gate electrode of the transistor Tr34 may be coupled to an input terminal AON and a gate electrode of the transistor Tr35. A drain electrode of the transistor Tr34 may be coupled to a source electrode of the transistor Tr3, a drain electrode of the transistor Tr4, and a source electrode of the transistor Tr9. The low-level potential VSS may be applied fixedly to a source electrode of the transistor Tr34.

A drain electrode of the transistor Tr35 may be coupled to the resistor R1, a drain electrode of the transistor Tr7, a gate electrode of the transistor Tr4, a drain electrode of the transistor Tr5, a drain electrode of the transistor Tr8, and a gate electrode of the transistor Tr2. The gate electrode of the transistor Tr35 may be coupled to the input terminal AON and the gate electrode of the transistor Tr34. The low-level potential VSS may be applied fixedly to a source electrode of the transistor Tr35.

A gate electrode of the transistor Tr36 may be coupled to a drain electrode of the transistor Tr36 and the input terminal AON. The source electrode of the transistor Tr36 may be coupled to the gate electrode of the transistor Tr36 and the input terminal AON. The drain electrode of the transistor Tr36 may be coupled to a gate electrode of the transistor Tr8, a drain electrode of the transistor Tr2, a source electrode of the transistor Tr1, the capacitor C1, and the output terminal OUT.

In the present embodiment, a first node turn-on unit may be implemented by the transistor Tr3, the input terminal IN, and the input terminal AONB, and an all-on control unit may be implemented by the transistors Tr34 to Tr36 and the input terminal AON. The all-on control unit may have a role of changing the level of the output terminal OUT toward an on level in accordance with signals AON and AONB supplied commonly to the unit circuits 11 of all the stages.

In the unit circuit 11 illustrated in FIG. 24, the control signal AON of a high-level potential may be input to the input terminal AON, and the control signal AONB of a low-level potential may be input to the input terminal AONB. Thus, the transistor Tr34 may be turned on, and the potential of a node n1 may thus become the low-level potential VSS. Furthermore, the transistor Tr35 may be turned on, and thus the potential of a node n2 may also become the low-level potential VSS. As a result, the transistors Tr1 and Tr2 may both be turned off. In addition, the transistor Tr36 may be turned on, and thus the output signals OUT of a high-level potential may be output outside from the unit circuits 11 of all the stages included in the shift register 10. In this manner, as the unit circuit 11 has the AON function, the shift register 10 can output the output signals OUT outside simultaneously from the unit circuits 11 of all the stages.

In the present embodiment, the transistors Tr1 to Tr3, Tr5 to Tr8, and Tr34 to Tr36 may not include light blocking films 12a and 12b. Meanwhile, the transistors Tr4 and Tr9 may each have a configuration identical to that of the transistor Tr illustrated in FIG. 5. In other words, only the transistors Tr4 and Tr9 may include the light blocking films 12a and 12b.

In the present embodiment, the transistor Tr4 may not enter a half-on state, and a shift in the threshold voltage caused by an optical shift in the transistor Tr9 can be suppressed. Therefore, a malfunction of the shift register 10 can be suppressed. Furthermore, since there is no need to add an auxiliary capacitor to the transistors Tr4 and Tr9, the size of the transistors Tr4 and Tr9 can be reduced, and the size of the unit circuit 11 and the shift register 10 can also be reduced as a result.

### Eighth Embodiment

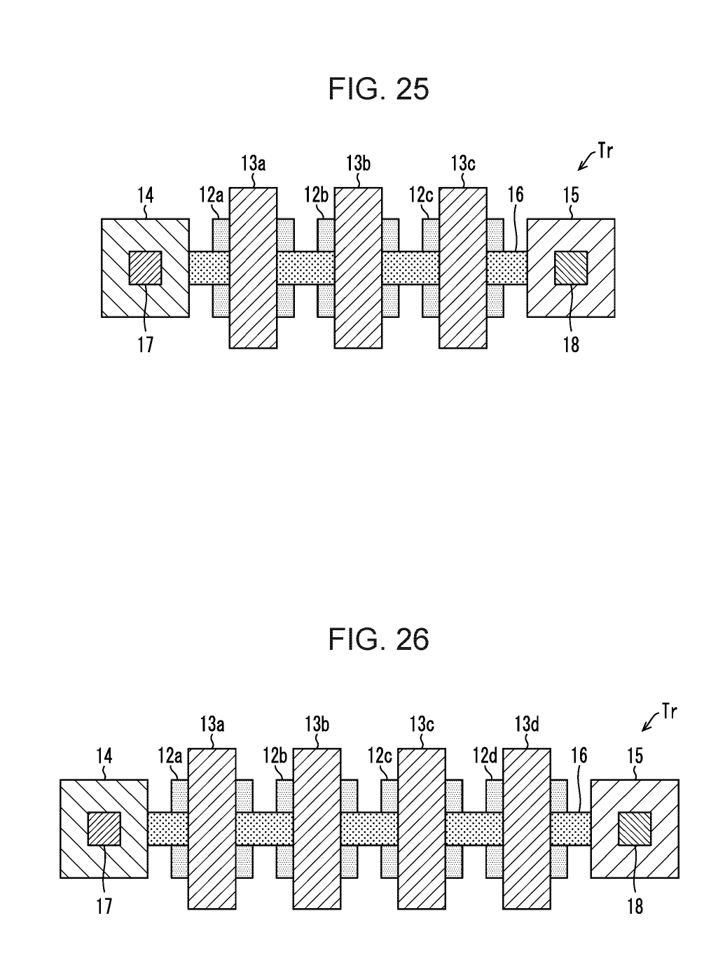

FIG. 25 illustrates a configuration example of a transistor Tr according to an eighth embodiment. The transistor Tr illustrated in FIG. 25 has a configuration in which a light blocking film 12 and a gate electrode 13 are each divided into three parts. The transistor Tr includes three light blocking films 12a to 12c, three gate electrodes 13a to 13c, a source electrode 14, a drain electrode 15, and a semiconductor portion 16. The light blocking films 12a to 12c are formed in a light blocking film layer, and the gate electrodes 13a to 13c are formed in a gate layer.

The gate electrodes 13a to 13c are formed between the source electrode 14 and the drain electrode 15 so as to overlap the semiconductor portion 16 as viewed in a plan view. The portion of the semiconductor portion 16 that overlaps any one of the gate electrodes 13a to 13c as viewed in a plan view serves as a channel portion of the transistor Tr. The light blocking films 12a to 12c are formed with a predetermined distance provided therebetween. The gate electrode 13a to the gate electrode 13c are formed with a predetermined distance provided therebetween. The light blocking film 12a and the gate electrode 13a overlap each other as viewed in a plan view, the light blocking film 12b and the gate electrode 13b overlap each other as viewed in a plan view, and the light blocking film 12c and the gate electrode 13c overlap each other as viewed in a plan view.

FIG. 26 illustrates another configuration example of the transistor Tr according to the eighth embodiment. The transistor Tr illustrated in FIG. 26 has a configuration in which the light blocking film 12 and the gate electrode 13 are each divided into four parts. The transistor Tr includes four light blocking films 12a to 12d, four gate electrodes 13a to 13d, the source electrode 14, the drain electrode 15, and the semiconductor portion 16. The light blocking films 12a to 12d are formed in the light blocking film layer, and the gate electrodes 13a to 13d are formed in the gate layer.

The gate electrodes 13a to 13d are formed between the source electrode 14 and the drain electrode 15 so as to overlap the semiconductor portion 16 as viewed in a plan view. The portion of the semiconductor portion 16 that overlaps any one of the gate electrodes 13a to 13d as viewed in a plan view serves as a channel portion of the transistor Tr. The light blocking films 12a to 12d are formed with a predetermined distance provided therebetween. The gate electrode 13a to the gate electrode 13d are formed with a predetermined distance provided therebetween. The light blocking film 12a and the gate electrode 13a overlap each other as viewed in a plan view, the light blocking film 12b and the gate electrode 13b overlap each other as viewed in a plan view, the light blocking film 12c and the gate electrode 13c overlap each other as viewed in a plan view, and the light blocking film 12d and the gate electrode 13d overlap each other as viewed in a plan view.

The transistor Tr illustrated in FIG. 25 and the transistor Tr illustrated in FIG. 26 each provide an effect similar to that of the transistor Tr illustrated in FIG. 5. Furthermore, the transistor Tr can have a configuration in which the light blocking film 12 and the gate electrode 13 are divided into five or more parts. In other words, it suffices that the transistor Tr have a plurality of gate electrodes 13 and a plurality of light blocking films 12 and that the plurality of light blocking films 12 overlap the respective gate electrodes 13 as viewed in a plan view and be electrically isolated.

### Ninth Embodiment

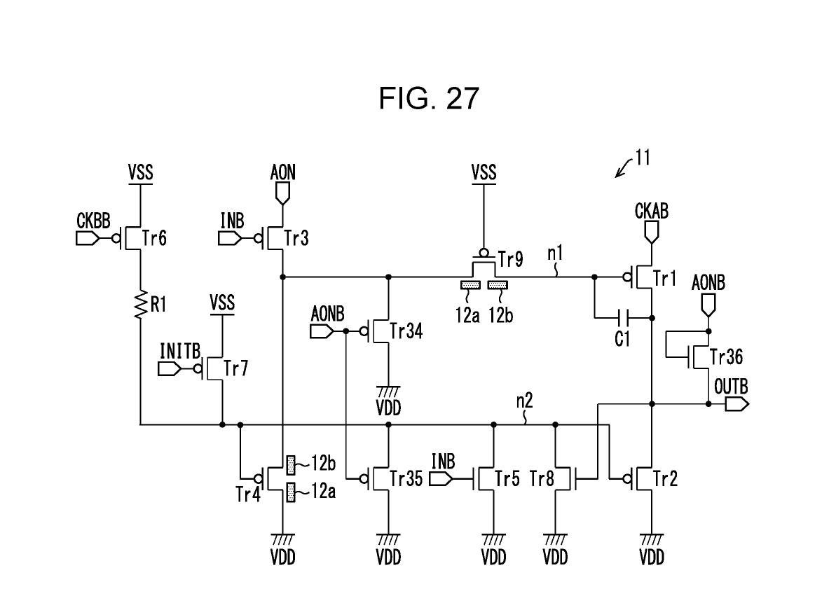

FIG. 27 illustrates a configuration example of a unit circuit 11 according to a ninth embodiment. The unit circuit 11 illustrated in FIG. 27 may include transistors Tr1 to Tr9 and Tr34 to Tr36, a capacitor C1, and a resistor R1. The transistors Tr1 to Tr9 and Tr34 to Tr36 may each be a p-channel transistor.

In the unit circuit 11 according to the present embodiment, the arrangement and the coupling of the transistors Tr1 to Tr9 and Tr34 to Tr36, the capacitor C1, and the resistor R1 are basically identical to those in the unit circuit 11 according to the seventh embodiment. The unit circuit 11 according to the present embodiment may differ from the unit circuit 11 according to the seventh embodiment in that the transistors Tr1 to Tr9 and Tr34 to Tr36 are each a p-channel transistor. In accordance with this difference, in the unit circuit 11 according to the present embodiment, the types of terminals to which the transistors Tr1 to Tr9 and Tr34 to Tr36 are coupled and the types of voltages applied to the transistors Tr1 to Tr9 and Tr34 to Tr36 may differ from those in the unit circuit 11 according to the seventh embodiment.

The details are as follows. A drain electrode of the transistor Tr1 may be coupled to a clock terminal CKAB. The high-level potential VDD may be applied fixedly to source electrodes of the transistors Tr2, Tr4, Tr5, Tr8, Tr34, and Tr35. A gate electrode of the transistor Tr3 may be coupled to an input terminal INB. A drain electrode of the transistor Tr3 may be coupled to an input terminal AON. A gate electrode of the transistor Tr5 may be coupled to an input terminal INB. A gate electrode of the transistor Tr6 may be coupled to a clock terminal CKBB. The low-level potential VSS may be applied fixedly to a drain electrode of the transistor Tr6. A gate electrode of the transistor Tr7 may be coupled to an initialization terminal INITB. The low-level potential VSS may be applied fixedly to a drain electrode of the transistor Tr7. The low-level potential VSS may be applied fixedly to a gate electrode of the transistor Tr9. The gate electrode of the transistor Tr34 and the gate electrode of the transistor Tr35 may be coupled to an input terminal AONB. A gate electrode of the transistor Tr36 may be coupled to a source electrode of the transistor Tr36 and the input terminal AONB. The source electrode of the transistor Tr36 may be coupled to the gate electrode of the transistor Tr36 and the input terminal AONB. A drain electrode of the transistor Tr36 may be coupled to a gate electrode of the transistor Tr8, a drain electrode of the transistor Tr2, a source electrode of the transistor Tr1, the capacitor C1, and an output terminal OUTB.

In the present embodiment, the transistors Tr1 to Tr3, Tr5 to Tr8, and Tr34 to Tr36 may not include light blocking films 12a and 12b. Meanwhile, the transistors Tr4 and Tr9 may each have a configuration identical to that of the transistor Tr illustrated in FIG. 5. In other words, the transistors Tr4 and Tr9 may each include the light blocking films 12a and 12b and gate electrodes 13a and 13b. Accordingly, the unit circuit 11 according to the present embodiment may provide an effect similar to that of the unit circuit 11 according to the seventh embodiment.

### Recapitulation

Aspect 1: A transistor, comprising: a channel portion; a first conducting electrode; a second conducting electrode; a plurality of control electrodes; and a plurality of light blocking films provided in a layer lower than a layer in which the plurality of control electrodes are provided, the plurality of light blocking films overlapping the respective control electrodes as viewed in a plan view, the plurality of light blocking films shielding the channel portion from light, the plurality of light blocking films being electrically isolated.

Aspect 2: A shift register having a plurality of stages for driving a plurality of scanning lines disposed in a display unit of a display device, wherein unit circuits constituting the respective stages each include a plurality of transistors that can be classified into a first group and a second group, the transistor in the first group having an on/off state thereof controlled with a relatively high on-duty, the transistor in the second group having an on/off state thereof controlled with a relatively low on-duty, and wherein only the transistor included in one of the first group and the second group is the transistor according to Aspect 1.

Aspect 3: The shift register according to Aspect 2, wherein of the plurality of transistors, the transistor that has the on/off state thereof controlled with an on-duty of no less than 50 percent is classified into the first group, and wherein the transistor that has the on/off state thereof controlled with an on-duty of less than 50 percent is classified into the second group.

Aspect 4: The shift register according to Aspect 2, wherein only a portion of the transistors included in one of the first group and the second group is the transistor according to Aspect 1.

Aspect 5: The shift register according to Aspect 2, wherein the transistor that is included in the first group and that is an n-channel transistor to a control electrode of which a positive bias keeps being applied is the transistor according to Aspect 1.

Aspect 6: The shift register according to Aspect 5, wherein the unit circuit includes an output node coupled to one of the plurality of scanning lines; an output control transistor having a control electrode, a first conducting electrode, and a second conducting electrode, the first conducting electrode being supplied with a clock signal, the second conducting electrode being coupled to the output node, the output control transistor being included in the second group; a first node coupled to the control electrode of the output control transistor; a first node turn-on unit having a transistor included in the second group, the first node turn-on unit being for changing a level of the first node toward an on level in accordance with an output signal output from an output node of another stage; a voltage dividing transistor having a control electrode, a first conducting electrode, and a second conducting electrode, the control electrode being supplied with an on-level potential, the first conducting electrode being coupled to the first node turn-on unit, the second conducting electrode being coupled to the first node, the voltage dividing transistor being included in the first group; an output node turn-off transistor having a control electrode, a first conducting electrode, and a second conducting electrode, the first conducting electrode being coupled to the output node, the second conducting electrode being supplied with an off-level potential, the output node turn-off transistor being included in the first group; a second node coupled to the control electrode of the output node turn-off transistor; and a first node turn-off transistor having a control electrode, a first conducting electrode, and a second conducting electrode, the control electrode being coupled to the second node, the first conducting electrode being coupled to the first node with the voltage dividing transistor interposed therebetween, the second conducting electrode being supplied with an off-level potential, and the first node turn-off transistor being included in the first group, and wherein only the voltage dividing transistor is the transistor according to Aspect 1.

Aspect 7: The shift register according to Aspect 2, wherein the transistor that is included in the first group and that is an n-channel transistor to a control electrode of which a positive bias is applied for an extended period of time is the transistor according to Aspect 1.

Aspect 8: The shift register according to Aspect 7, wherein the unit circuit includes an output node coupled to one of the plurality of scanning lines; an output control transistor having a control electrode, a first conducting electrode, and a second conducting electrode, the first conducting electrode being supplied with a clock signal, the second conducting electrode being coupled to the output node, the output control transistor being included in the second group; a first node coupled to the control electrode of the output control transistor; a first node turn-on unit having a transistor included in the second group, the first node turn-on unit being for changing a level of the first node toward an on level in accordance with an output signal output from an output node of another stage; an output node turn-off transistor having a control electrode, a first conducting electrode, and a second conducting electrode, the first conducting electrode being coupled to the output node, the second conducting electrode being supplied with an off-level potential, the output node turn-off transistor being included in the first group; a second node coupled to the control electrode of the output node turn-off transistor; and a first node turn-off transistor having a control electrode, a first conducting electrode, and a second conducting electrode, the control electrode being coupled to the second node, the first conducting electrode being coupled to the first node, the second conducting electrode being supplied with an off-level potential, the first node turn-off transistor being included in the first group, and wherein only the output node turn-off transistor and the first node turn-off transistor are each the transistor according to Aspect 1.

Aspect 9: The shift register according to Aspect 2, wherein the transistor that is included in the second group and that is a p-channel transistor to a control electrode of which a negative bias is applied for an extended period of time is the transistor according to Aspect 1.

Aspect 10: The shift register according to Aspect 9, wherein the unit circuit includes an output node coupled to one of the plurality of scanning lines; a set-reset flip-flop that outputs a first output signal and a second output signal in accordance with an output signal output from an output node in a stage preceding the unit circuit and an output signal output from an output node following the unit circuit; a first output control transistor having a control electrode, a first conducting electrode, and a second conducting electrode, the control electrode being supplied with the first output signal, the first conducting electrode being supplied with a clock signal, the second conducting electrode being coupled to the output node, the first output control transistor being included in the second group; a second output control transistor having a control electrode, a first conducting electrode, and a second conducting electrode, the control electrode being supplied with the second output signal, the first conducting electrode being supplied with the clock signal, the second conducting electrode being coupled to the output node, the second output control transistor being included in the second group; and an output node turn-off transistor having a control electrode, a first conducting electrode, and a second conducting electrode, the control electrode being supplied with the second output signal, the first conducting electrode being coupled to the output node, the second conducting electrode being supplied with an off-level potential, the output node turn-off transistor being included in the first group, and wherein only the second output control transistor is the transistor according to Aspect 1.

Aspect 11: The shift register according to Aspect 2, wherein a transistor in which the light blocking films are provided is the transistor that is included in the second group and that is an n-channel transistor to a control electrode of which a negative bias is applied for an extended period of time.

Aspect 12: The shift register according to Aspect 11, wherein the unit circuit includes an output node coupled to one of the plurality of scanning lines; an output control transistor having a control electrode, a first conducting electrode, and a second conducting electrode, the first conducting electrode being supplied with a clock signal, the second conducting electrode being coupled to the output node, the output control transistor being included in the second group; a first node coupled to the control electrode of the output control transistor; a first node turn-on unit having a transistor included in the second group, the first node turn-on unit being for changing a level of the first node toward an on level in accordance with an output signal output from an output node of another stage; an output node turn-off transistor having a control electrode, a first conducting electrode, and a second conducting electrode, the first conducting electrode being coupled to the output node, the second conducting electrode being supplied with an off-level potential, the output node turn-off transistor being included in the first group; a second node coupled to the control electrode of the output node turn-off transistor; and a first node turn-off transistor having a control electrode, a first conducting electrode, and a second conducting electrode, the control electrode being coupled to the second node, the first conducting electrode being coupled to the first node, the second conducting electrode being supplied with an off-level potential, the first node turn-off transistor being included in the first group, and wherein only the output control transistor is the transistor according to Aspect 1.

Aspect 13: The shift register according to Aspect 2, wherein the unit circuit includes an output node coupled to one of the plurality of scanning lines; an output control transistor having a control electrode, a first conducting electrode, and a second conducting electrode, the first conducting electrode being supplied with a clock signal, the second conducting electrode being coupled to the output node, the output control transistor being included in the second group; a first node coupled to the control electrode of the output control transistor; a first node turn-on unit having a transistor included in the second group, the first node turn-on unit being for changing a level of the first node toward an on level in accordance with an output signal output from an output node of another stage; a voltage dividing transistor having a control electrode, a first conducting electrode, and a second conducting electrode, the control electrode being supplied with an on-level potential, the first conducting electrode being coupled to the first node turn-on unit, the second conducting electrode being coupled to the first node, the voltage dividing transistor being included in the first group; an output node turn-off transistor having a control electrode, a first conducting electrode, and a second conducting electrode, the first conducting electrode being coupled to the output node, the second conducting electrode being supplied with an off-level potential, the output node turn-off transistor being included in the first group; a second node coupled to the control electrode of the output node turn-off transistor; a first node turn-off transistor having a control electrode, a first conducting electrode, and a second conducting electrode, the control electrode being coupled to the second node, the first conducting electrode being coupled to the first node with the voltage dividing transistor interposed therebetween, the second conducting electrode being supplied with an off-level potential, the first node turn-off transistor being included in the first group; and an all-on control unit that changes a level of the output node toward an on level in accordance with a control signal supplied commonly to the unit circuits of all the stages, and wherein only the first node turn-off transistor and the voltage dividing transistor are each the transistor according to Aspect 1.

Aspect 14: A shift register having a plurality of stages for driving a plurality of scanning lines disposed in a display unit of a display device, wherein unit circuits constituting the respective stages each include a plurality of transistors including a transistor of a first conductivity type and a transistor of a second conductivity type, wherein only a portion of the plurality of transistors is the transistor according to Aspect 1, and wherein the transistor of the first conductivity type having an on/off state thereof controlled with a relatively low on-duty and the transistor of the second conductivity type having an on/off state thereof controlled with a relatively high on-duty are each the transistor according to the Aspect 1.

Aspect 15: The shift register according to Aspect 14, wherein the transistor of the first conductivity type is an n-channel transistor, wherein the transistor of the second conductivity type is a p-channel transistor, and wherein an n-channel transistor to a control electrode of which a negative bias is applied for an extended period of time and a p-channel transistor to a control electrode of which a positive bias is applied for an extended period of time are each the transistor according to Aspect 1.

The present disclosure is not limited to the embodiments described above and can have various modifications made thereto within the scope set forth in the claims. An embodiment obtained by combining, as appropriate, techniques disclosed in different embodiments is also encompassed by the technical scope of the present disclosure. A new technical feature can be conceived of by combining techniques disclosed in each of the embodiments.

The present disclosure contains subject matter related to that disclosed in Japanese Priority Patent Application JP 2017-213673 filed in the Japan Patent Office on Nov. 6, 2017, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A transistor, comprising
a channel portion;
a first conducting electrode;
a second conducting electrode;
a plurality of control electrodes; and
a plurality of light blocking films provided in a layer lower than a layer in which the plurality of control electrodes are provided, the plurality of light blocking films overlapping the respective control electrodes as viewed in a plan view, the plurality of light blocking films shielding the channel portion from light, the plurality of light blocking films being electrically isolated.

2. A shift register having a plurality of stages for driving a plurality of scanning lines disposed in a display unit of a display device,
wherein unit circuits constituting the respective stages each include a plurality of transistors that can be classified into a first group and a second group, the transistor in the first group having an on/off state thereof controlled with a relatively high on-duty, the transistor in the second group having an on/off state thereof controlled with a relatively low on-duty, and
wherein only the transistor included in one of the first group and the second group is the transistor according to claim 1.

3. The shift register according to claim 2,
wherein of the plurality of transistors,
the transistor that has the on/off state thereof controlled with an on-duty of no less than 50 percent is classified into the first group, and
the transistor that has the on/off state thereof controlled with an on-duty of less than 50 percent is classified into the second group.

4. The shift register according to claim 2,
wherein only a portion of the transistors included in one of the first group and the second group is the transistor according to claim 1.

5. The shift register according to claim 2,
wherein the transistor that is included in the first group and that is an n-channel transistor to a control electrode of which a positive bias keeps being applied is the transistor according to claim 1.

6. The shift register according to claim 5,
wherein the unit circuit includes
an output node coupled to one of the plurality of scanning lines,
an output control transistor having a control electrode, a first conducting electrode, and a second conducting electrode, the first conducting electrode being supplied with a clock signal, the second conducting electrode being coupled to the output node, the output control transistor being included in the second group,
a first node coupled to the control electrode of the output control transistor,
a first node turn-on unit having a transistor included in the second group, the first node turn-on unit being for changing a level of the first node toward an on level in accordance with an output signal output from an output node of another stage,
a voltage dividing transistor having a control electrode, a first conducting electrode, and a second conducting electrode, the control electrode being supplied with an on-level potential, the first conducting electrode being coupled to the first node turn-on unit, the second conducting electrode being coupled to the first node, the voltage dividing transistor being included in the first group,
an output node turn-off transistor having a control electrode, a first conducting electrode, and a second conducting electrode, the first conducting electrode being coupled to the output node, the second conducting electrode being supplied with an off-level potential, the output node turn-off transistor being included in the first group,
a second node coupled to the control electrode of the output node turn-off transistor, and
a first node turn-off transistor having a control electrode, a first conducting electrode, and a second conducting electrode, the control electrode being coupled to the second node, the first conducting electrode being coupled to the first node with the voltage dividing transistor interposed therebetween, the second conducting electrode being supplied with an off-level potential, the first node turn-off transistor being included in the first group, and
wherein only the voltage dividing transistor is the transistor according to claim 1.

7. The shift register according to claim 2,
wherein the transistor that is included in the first group and that is an n-channel transistor to a control electrode of which a positive bias is applied for an extended period of time is the transistor according to claim 1.

8. The shift register according to claim 7,
wherein the unit circuit includes
an output node coupled to one of the plurality of scanning lines,
an output control transistor having a control electrode, a first conducting electrode, and a second conducting electrode, the first conducting electrode being supplied with a clock signal, the second conducting electrode being coupled to the output node, the output control transistor being included in the second group,
a first node coupled to the control electrode of the output control transistor,
a first node turn-on unit having a transistor included in the second group, the first node turn-on unit being for changing a level of the first node toward an on level in accordance with an output signal output from an output node of another stage,
an output node turn-off transistor having a control electrode, a first conducting electrode, and a second conducting electrode, the first conducting electrode being coupled to the output node, the second conducting electrode being supplied with an off-level potential, the output node turn-off transistor being included in the first group,
a second node coupled to the control electrode of the output node turn-off transistor, and
a first node turn-off transistor having a control electrode, a first conducting electrode, and a second conducting electrode, the control electrode being coupled to the second node, the first conducting electrode being coupled to the first node, the second conducting electrode being supplied with an off-level potential, the first node turn-off transistor being included in the first group, and
wherein only the output node turn-off transistor and the first node turn-off transistor are each the transistor according to claim 1.

9. The shift register according to claim 2,
wherein the transistor that is included in the second group and that is a p-channel transistor to a control electrode of which a negative bias is applied for an extended period of time is the transistor according to claim 1.

10. The shift register according to claim 9,
wherein the unit circuit includes
an output node coupled to one of the plurality of scanning lines,
a set-reset flip-flop that outputs a first output signal and a second output signal in accordance with an output signal output from an output node in a stage preceding the unit circuit and an output signal output from an output node following the unit circuit,
a first output control transistor having a control electrode, a first conducting electrode, and a second conducting electrode, the control electrode being supplied with the first output signal, the first conducting electrode being supplied with a clock signal, the second conducting electrode being coupled to the output node, the first output control transistor being included in the second group,
a second output control transistor having a control electrode, a first conducting electrode, and a second conducting electrode, the control electrode being supplied with the second output signal, the first conducting electrode being supplied with the clock signal, the second conducting electrode being coupled to the output node, the second output control transistor being included in the second group, and
an output node turn-off transistor having a control electrode, a first conducting electrode, and a second conducting electrode, the control electrode being supplied with the second output signal, the first conducting electrode being coupled to the output node, the second conducting electrode being supplied with an off-level potential, the output node turn-off transistor being included in the first group, and
wherein only the second output control transistor is the transistor according to claim 1.

11. The shift register according to claim 2,
wherein a transistor in which the light blocking films are provided is the transistor that is included in the second group and that is an n-channel transistor to a control electrode of which a negative bias is applied for an extended period of time.

12. The shift register according to claim 11,
wherein the unit circuit includes
an output node coupled to one of the plurality of scanning lines,
an output control transistor having a control electrode, a first conducting electrode, and a second conducting electrode, the first conducting electrode being supplied with a clock signal, the second conducting electrode being coupled to the output node, the output control transistor being included in the second group,
a first node coupled to the control electrode of the output control transistor,
a first node turn-on unit having a transistor included in the second group, the first node turn-on unit being for changing a level of the first node toward an on level in accordance with an output signal output from an output node of another stage,
an output node turn-off transistor having a control electrode, a first conducting electrode, and a second conducting electrode, the first conducting electrode being coupled to the output node, the second conducting electrode being supplied with an off-level potential, the output node turn-off transistor being included in the first group,
a second node coupled to the control electrode of the output node turn-off transistor, and
a first node turn-off transistor having a control electrode, a first conducting electrode, and a second conducting electrode, the control electrode being coupled to the second node, the first conducting electrode being coupled to the first node, the second conducting electrode being supplied with an off-level potential, the first node turn-off transistor being included in the first group, and
wherein only the output control transistor is the transistor according to claim 1.

13. The shift register according to claim 2,
wherein the unit circuit includes
an output node coupled to one of the plurality of scanning lines,
an output control transistor having a control electrode, a first conducting electrode, and a second conducting electrode, the first conducting electrode being supplied with a clock signal, the second conducting electrode being coupled to the output node, the output control transistor being included in the second group,
a first node coupled to the control electrode of the output control transistor,
a first node turn-on unit having a transistor included in the second group, the first node turn-on unit being for changing a level of the first node toward an on level in accordance with an output signal output from an output node of another stage,
a voltage dividing transistor having a control electrode, a first conducting electrode, and a second conducting electrode, the control electrode being supplied with an on-level potential, the first conducting electrode being coupled to the first node turn-on unit, the second conducting electrode being coupled to the first node, the voltage dividing transistor being included in the first group,
an output node turn-off transistor having a control electrode, a first conducting electrode, and a second conducting electrode, the first conducting electrode being coupled to the output node, the second conducting electrode being supplied with an off-level potential, the output node turn-off transistor being included in the first group,
a second node coupled to the control electrode of the output node turn-off transistor,
a first node turn-off transistor having a control electrode, a first conducting electrode, and a second conducting electrode, the control electrode being coupled to the second node, the first conducting electrode being coupled to the first node with the voltage dividing transistor interposed therebetween, the second conducting electrode being supplied with an off-level potential, the first node turn-off transistor being included in the first group, and
an all-on control unit that changes a level of the output node toward an on level in accordance with a control signal supplied commonly to the unit circuits of all the stages, and
wherein only the first node turn-off transistor and the voltage dividing transistor are each the transistor according to claim 1.

14. A shift register having a plurality of stages for driving a plurality of scanning lines disposed in a display unit of a display device,
wherein unit circuits constituting the respective stages each include a plurality of transistors including a transistor of a first conductivity type and a transistor of a second conductivity type,
wherein only a portion of the plurality of transistors is the transistor according to claim 1, and
wherein the transistor of the first conductivity type having an on/off state thereof controlled with a relatively low on-duty and the transistor of the second conductivity type having an on/off state thereof controlled with a relatively high on-duty are each the transistor according to the claim 1.

15. The shift register according to claim 14,
wherein the transistor of the first conductivity type is an n-channel transistor,
wherein the transistor of the second conductivity type is a p-channel transistor, and
wherein an n-channel transistor to a control electrode of which a negative bias is applied for an extended period of time and a p-channel transistor to a control electrode of which a positive bias is applied for an extended period of time are each the transistor according to claim 1.
